(19) United States
(12) Patent Application Publication
(10) Pub. No.: US 2026/0090232 A1
(43) Pub. Date: Mar. 26, 2026

(54) DISPLAY DEVICE AND METHOD FOR PRODUCING DISPLAY DEVICE

(71) Applicant: Sharp Display Technology Corporation, Kameyama City, Mie (JP)

(72) Inventor: YUSUKE SAKAKIBARA, Sakai City, Osaka (JP)

(21) Appl. No.: 19/111,664

(22) PCT Filed: Sep. 26, 2022
(86) PCT No.: PCT/JP2022/035569

§ 371 Date: Mar. 13, 2025

(51) Int. Cl. H10K 59/00; H10K 50/115; H10K 59/12

(52) U.S. Cl. CPC H10K 59/771; H10K 59/1201; H10K 50/115

(57) ABSTRACT

The display device includes a substrate, a plurality of light-emitting elements including a quantum dot layer including a plurality of quantum dots and a first inorganic material with which spaces between the plurality of quantum dots are filled, and an inorganic layer. The inorganic layer is located between the at least two light-emitting elements. Furthermore, the inorganic layer contains a second inorganic material including a semiconductor having a band gap of 2.8 eV or more or an insulator.

### TECHNICAL FIELD

The disclosure relates to a display device that is provided with a light-emitting element containing quantum dots as a light-emitting material, and a manufacturing method of the display device.

### BACKGROUND ART

PTL 1 discloses a technique for collectively performing a film formation of an electron blocking layer between a hole transport layer and a light-emitting layer of each light-emitting element on a substrate including light-emitting elements.

### CITATION LIST

### Patent Literature

PTL 1: JP 2012-204329 A

### SUMMARY

### Technical Problem

In a display device including a light-emitting element, in order to achieve a display device having a high color gamut, it is conceivable to employ a quantum dot having features of a narrow half width of a light emission wavelength as a light-emitting layer of the light-emitting element. In this case, in order to ensure the reliability of the light-emitting element and to suppress a decrease in luminance with respect to the driving time, there is a problem in that both protection of the quantum dot in the light-emitting layer and manufacturability of the light-emitting layer need to be achieved. In particular, the size of each pixel has been reduced due to high resolution of a display in recent years, and thus highly accurate patterning is required in a manufacturing process of the above-described light-emitting layer.

### Solution to Problem

A display device according to an embodiment of the disclosure includes a substrate, a plurality of light-emitting elements on the substrate, the plurality of light-emitting elements including a first electrode, a second electrode, a quantum dot layer located between the first electrode and the second electrode and including a plurality of quantum dots and a first inorganic material with which spaces between the plurality of quantum dots are filled, and an inorganic layer located between at least two of the light-emitting elements and including a second inorganic material including a semiconductor having a band gap of 2.8 eV or more or an insulator.

A method of manufacturing a display device according to an embodiment of the disclosure includes providing a substrate, forming a plurality of light-emitting elements including forming a plurality of first electrodes on the substrate, forming a plurality of quantum dot layers each including a plurality of quantum dots and a first inorganic material with which spaces between the plurality of quantum dots are filled at a position overlapping a respective one of the first electrodes in a plan view of the substrate, and forming at least one second electrode at a position overlapping a respective one of the first electrodes in a plan view of the substrate; and forming an inorganic layer located between at least two of the light-emitting elements and including a second inorganic material including a semiconductor having a band gap of 2.8 eV or more or an insulator.

### Advantageous Effects of Disclosure

To achieve a display device having high reliability and high resolution.

### BRIEF DESCRIPTION OF DRAWINGS

FIG. 1 is a schematic cross-sectional side view of a display device according to a first embodiment, a schematic enlarged view of the cross-sectional side view, and a schematic view illustrating a first inorganic material with which spaces between quantum dots are filled.

FIG. 2 is a schematic plan view of the display device according to the first embodiment.

FIG. 3 is a schematic enlarged view of one pixel of the display device according to the first embodiment.

FIG. 4 is a flowchart illustrating an example of a manufacturing method of the display device according to the first embodiment.

FIG. 5 includes process cross-sectional views of the example of the manufacturing method of the display device according to the first embodiment.

FIG. 6 includes other process cross-sectional views of the example of the manufacturing method of the display device according to the first embodiment.

FIG. 7 includes other process cross-sectional views of the example of the manufacturing method of the display device according to the first embodiment.

FIG. 8 includes other process cross-sectional views of the example of the manufacturing method of the display device according to the first embodiment.

FIG. 9 includes other process cross-sectional views of the example of the manufacturing method of the display device according to the first embodiment.

FIG. 10 includes schematic cross-sectional side views of display devices for comparing display devices according to a first comparative embodiment and the first embodiment.

FIG. 11 is a schematic cross-sectional side view of a display device according to a second embodiment.

FIG. 12 is a schematic cross-sectional side view of a display device according to a third embodiment.

FIG. 13 is a schematic cross-sectional side view of a display device according to a fourth embodiment.

FIG. 14 is a flowchart illustrating an example of a manufacturing method of the display device according to the fourth embodiment.

FIG. 15 includes process cross-sectional views of the example of the manufacturing method of the display device according to the fourth embodiment.

FIG. 16 includes other process cross-sectional views of the example of the manufacturing method of the display device according to the fourth embodiment.

FIG. 17 is schematic cross-sectional side views of display devices for comparing display devices according to a second comparative embodiment and the fourth embodiment.

FIG. 18 is another schematic cross-sectional side views of display devices for comparing display devices according to the second comparative embodiment and the fourth embodiment.

### DESCRIPTION OF EMBODIMENTS

### First Embodiment

### Overview of Display Device

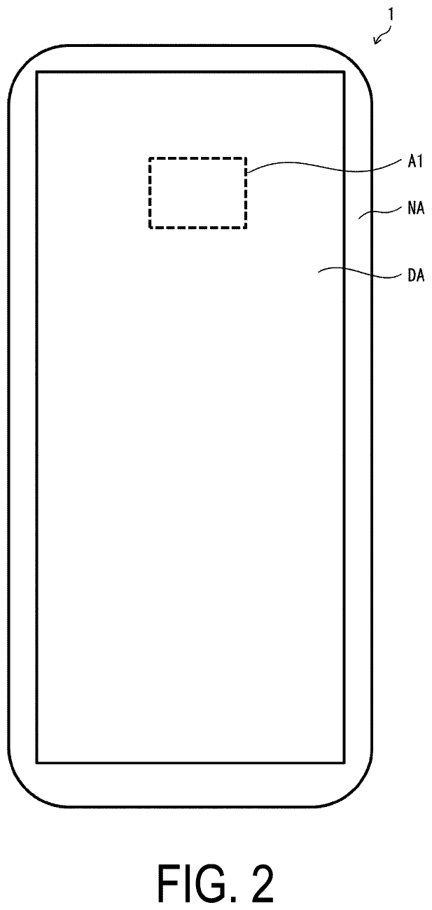

FIG. 2 is a schematic plan view of a display device 1 according to the present embodiment. The display device 1 includes a display portion DA and a frame portion NA formed around an outer periphery of the display portion DA. The display device 1 performs display in the display portion DA by controlling light emission from each of a plurality of light-emitting elements described later formed in the display portion DA. In the frame portion NA, a driver or the like for driving each of the plurality of light-emitting elements of the display portion DA may be formed.

### Subpixel of Display Portion

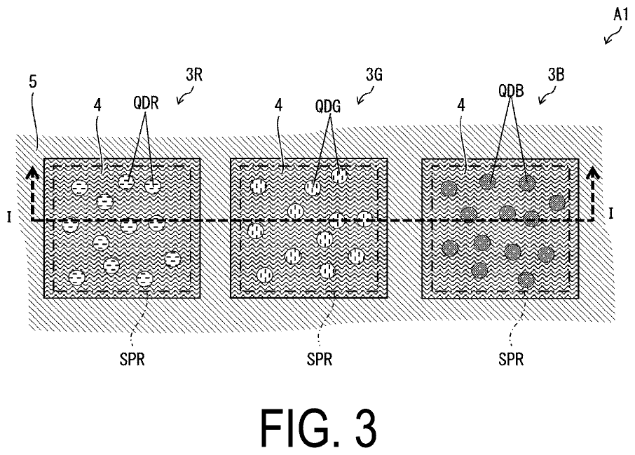

FIG. 3 is a schematic enlarged view illustrating one pixel of the display portion DA in the schematic plan view of the display device 1 illustrated in FIG. 2, and particularly an enlarged view illustrating a region A1 illustrated in FIG. 2. FIG. 3 is illustrated through a cathode 35 and an electron transport layer 34, which will be described later.

As will be described later, the display device 1 includes a plurality of light-emitting elements on a substrate. In particular, in the display device 1, each of a red subpixel SPR, a green subpixel SPG, and a blue subpixel SPB includes a light-emitting element, and the display device 1 performs display in the display portion DA by individually driving each light-emitting element. For example, the display device 1 includes a red light-emitting element 3R which is a component on the red subpixel SPR, a green light-emitting element 3G which is a component on the green subpixel SPG, and a blue light-emitting element 3B which is a component on the blue subpixel SPB. The display device 1 may form one pixel by the red light-emitting element 3R, the green light-emitting element 3G, and the blue light-emitting element 3B. As will be described later, the display device 1 includes an inorganic layer 5 at a position including a position overlapping the periphery of each light-emitting element in a plan view of a substrate 2 of the display device 1. In the present embodiment, the plan view of the substrate 2 refers to viewing the substrate 2 from a direction perpendicular to an upper face of the substrate 2, and may be synonymous with viewing the display device 1 from a direction perpendicular to an upper face of the display portion DA of the display device 1, the upper face being the light-emitting surface.

### Outline of Substrate and Light-Emitting Element Layer

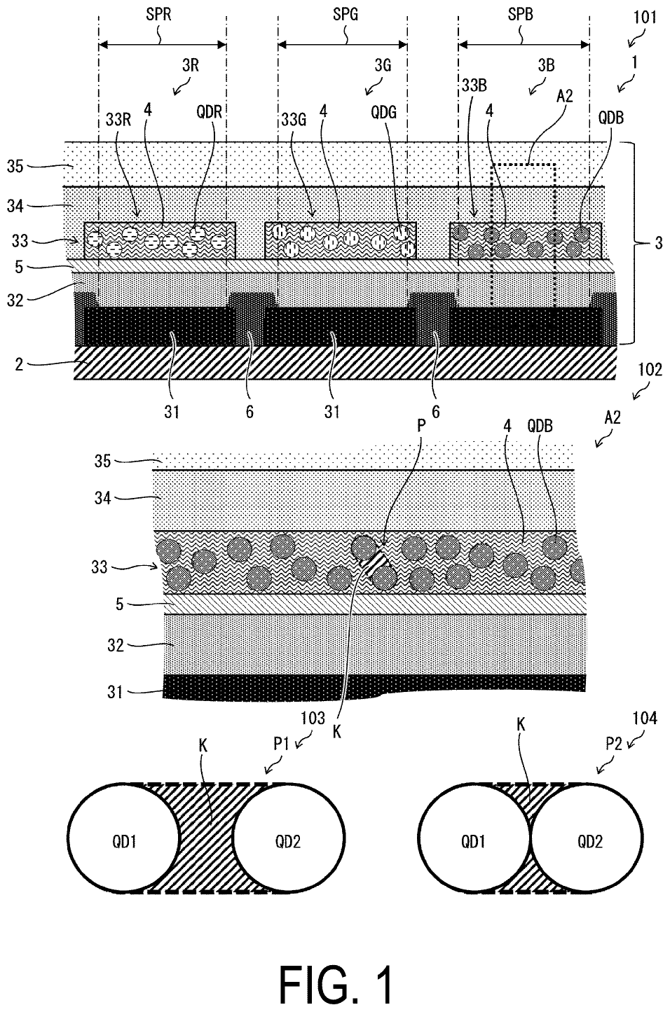

FIG. 1 is a schematic cross-sectional side view 101 of the display device 1 according to the present embodiment, a schematic enlarged view 102 of the schematic cross-sectional side view 101, and schematic views 103 and 104 for illustrating a first inorganic material filling a space between quantum dots to be described later.

The schematic cross-sectional side view 101 of the display device 1 illustrated in FIG. 1 is an arrow cross-sectional view taken along line I-I illustrated in FIG. 3, in other words, a view illustrating a cross-sectional side view in a plane perpendicular to the upper face of the display portion DA and passing through the red light-emitting element 3R, the green light-emitting element 3G, and the blue light-emitting element 3B. Hereinafter, in this specification, each of the schematic cross-sectional side views of the display device illustrates a cross-section at the same position as the cross-section illustrated in the schematic cross-sectional side view 101 of the display device 1 illustrated in FIG. 1.

The schematic enlarged view 102 of the display device 1 illustrated in FIG. 1 is an enlarged view of a region A2 illustrated in the schematic cross-sectional side view 101 of the display device 1.

The schematic views 103 and 104 for illustrating the first inorganic material filling the space between the quantum dots illustrated in FIG. 1 are views respectively illustrating one of two examples of a pair P of two blue quantum dots QDB and a region (space) K therebetween, which will be described later, illustrated in the schematic enlarged view 102 of the display device 1. In particular, the schematic views 103 and 104 are views respectively illustrating one of a pair P1 and a pair P2, which are examples of a pair of a quantum dot QD1 and a quantum dot QD2.

The display device 1 includes the substrate 2 such as a glass substrate or a film substrate and a light-emitting element layer 3 on the substrate 2 in the display portion DA. The light-emitting element layer 3 includes an anode 31 as a first electrode, a hole transport layer 32 as a first charge transport layer, an inorganic layer 5, a quantum dot layer 33, an electron transport layer 34 as a second charge transport layer, and a cathode 35 as a second electrode in this order from the substrate 2 side toward the upper face side of the display portion DA.

The anode 31 is formed in an island shape for each subpixel, for example, and is connected to each of pixel circuits (not illustrated) formed on the substrate 2. The hole transport layer 32, the electron transport layer 34, and the cathode 35 are formed in common to the plurality of subpixels.

The anode 31 and the cathode 35 are electrodes each containing a conductive material and are electrically connected to the hole transport layer 32 and the electron transport layer 34, respectively. When a voltage is applied to at least one of the anode 31 or the cathode 35, holes and electrons are injected from the anode 31 and the cathode 35 into the hole transport layer 32 and the electron transport layer 34, respectively. In the present embodiment, the display device 1 may control light emission from each light-emitting element by individually driving the anode 31 while applying a predetermined voltage to the cathode 35.

In the present embodiment, each of the red subpixel SPR, the green subpixel SPG, and the blue subpixel SPB is formed at a position where a smaller electrode of the electrodes of the light-emitting elements is in contact with the charge transport layer adjacent to the smaller electrode in a plan view of the substrate 2. In other words, in the present embodiment, each of the red subpixel SPR, the green subpixel SPG, and the blue subpixel SPB is formed at a position where each anode 31 and a respective one of the hole transport layers 32 are in contact with each other in a plan view of the substrate 2. In still other words, each of the red subpixel SPR, the green subpixel SPG, and the blue subpixel SPB is formed in a region where a respective one of the anode 31 is exposed from the bank 6 described later in a plan view of the substrate 2.

As described above, the red light-emitting element 3R, the green light-emitting element 3G, and the blue light-emitting element 3B are located in the red subpixel SPR, the green subpixel SPG, and the blue subpixel SPB, respectively. Thus, in the present embodiment, in a plan view of the substrate 2, a portion overlapping a position where each anode 31 is in contact with a respective one of the hole transport layers 32 is a range of a respective one of the red light-emitting element 3R, the green light-emitting element 3G, and the blue light-emitting element 3B.

At least one of the anode 31 or the cathode 35 is a transparent electrode transmitting visible light. As the transparent electrode, for example, ITO, IZO, SnO₂, or FTO may be used. Alternatively, one of the anode 31 and the cathode 35 may be a reflective electrode. The reflective electrode may contain a metal material having a high reflectivity of visible light, and the metal material may be, for example, Al, Ag, Cu, or Au alone or an alloy thereof.

The hole transport layer 32 is a layer that transports holes injected from the anode 31 to the quantum dot layer 33. As a material of the hole transport layer 32, an organic or inorganic material having hole transport properties employed in a light-emitting element containing quantum dots or the like in related art can be used. Examples of the material having hole transport properties include poly[(9,9-dioctylfluorenyl-2,7-diyl)-co-(4,4′-(N-4-sec-butylphenyl)) diphenylamine)](abbreviated “TFB”), poly[N,N′-bis(4-butylphenyl)-N,N′-bis(phenyl)-benzidine](abbreviated “p-TPD”), and polyvinyl carbazole (abbreviated “PVK”). As the hole transport layer 32, only one type of these materials having hole transport properties may be contained, or two or more types thereof may be mixed and contained as appropriate.

The light-emitting element layer 3 may include a hole injection layer between the anode 31 and the hole transport layer 32. Examples of a material of the hole injection layer include a composite (abbreviated “PEDOT:PSS”) of poly(3,4-ethylenedioxythiophene) (PEDOT) and polystyrene sulfonic acid (PSS), nickel oxide (NiO), and copper thiocyanate (CuSCN). As the hole injection layer, only one type of these materials may be contained, or two or more types thereof may be mixed and contained as appropriate.

The electron transport layer 34 is a layer that transports electrons injected from the cathode 35 to the quantum dot layer 33. As a material of the electron transport layer 34, an organic or inorganic material having electron transport properties employed in a light-emitting element containing quantum dots or the like in related art can be used. Examples of the material having electron transport properties include zinc oxide (ZnO) nano particles and magnesium zinc oxide (MgZnO) nano particles. As the electron transport layer 34, only one type of these materials having electron transport properties may be contained, or two or more types thereof may be mixed and contained as appropriate. In the present embodiment, the electron transport layer 34 may partition a red quantum dot layer 33R, a green quantum dot layer 33G, and a blue quantum dot layer 33B, which will be described later, for each subpixel.

### Quantum Dot

The quantum dot layer 33 includes the red quantum dot layer 33R, the green quantum dot layer 33G, and the blue quantum dot layer 33B. The red quantum dot layer 33R, the green quantum dot layer 33G, and the blue quantum dot layer 33B are formed at positions overlapping the red subpixel SPR, the green subpixel SPG, and the blue subpixel SPB, respectively, in a plan view of the substrate 2.

The red quantum dot layer 33R, the green quantum dot layer 33G, and the blue quantum dot layer 33B contain a plurality of red quantum dots QDR, a plurality of green quantum dots QDG, and a plurality of blue quantum dots QDB, respectively, as the quantum dots. When each light-emitting element is driven, holes are injected into each quantum dot from the anode 31 via the hole transport layer 32, and electrons are injected into each quantum dot from the cathode 35 via the electron transport layer 34.

The red quantum dot QDR, the green quantum dot QDG, and the blue quantum dot QDB are light-emitting materials that emit red light, green light, and blue light, respectively, by excitons generated by recombination of injected holes and electrons. Any of the quantum dots contained in the quantum dot layer 33 may employ a known quantum dot such as a core/shell structure.

In the disclosure, the “quantum dot” is a dot having a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-like three-dimensional shape, a branch-like three-dimensional shape, or a three-dimensional shape having unevenness on the surface, or a combination thereof.

The quantum dot typically may be composed of a semiconductor. The semiconductor may have a constant band gap. The semiconductor may be a material capable of emitting light and may include at least a material which will be described below. The semiconductor may emit each of red light, green light, and blue light. The semiconductor includes, for example, at least one kind selected from the group consisting of a group II-VI compound, a group III-V compound, and a chalcogenide and a perovskite compound. Note that the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element.

Examples of the group II-VI compound include, for example, at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include, for example, at least one kind selected from the group consisting of GaAs, GaP, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br, and I.

Here, the numbering of groups of an element by using Roman numerals is numbering based on the old International Union of Pure and Applied Chemistry (IUPAC) system or old Chemical Abstracts Service (CAS) system, and the numbering of groups of an element by using Arabic numerals is numbering based on the current IUPAC system.

In the present embodiment, the blue light refers to, for example, light having a light emission central wavelength in a wavelength band 380 nm or more and 500 nm or less. The green light refers to, for example, light having an emission center wavelength in a wavelength band of greater than 500 nm and equal to or less than 600 nm. Furthermore, the red light is light having the light-emitting central wavelength in a wavelength band longer than 600 nm and shorter than or equal to 780 nm.

### First Inorganic Material

Furthermore, each of the red quantum dot layer 33R, the green quantum dot layer 33G, and the blue quantum dot layer 33B includes a first inorganic material 4 that fills spaces between a plurality of the quantum dots.

“The first inorganic material 4 fills the space between the plurality of quantum dots” refers to filling a region K between the quantum dot QD1 and the quantum dot QD2 as illustrated in the schematic view 103 of the pair P1 illustrated in FIG. 1. In the cross-section of the quantum dot layer 33, the region K is a region surrounded by two straight lines in contact with the opposing outer peripheries of the quantum dot QD1 and the quantum dot QD2 and the outer peripheries of the quantum dot QD1 and the quantum dot QD2. Thus, as illustrated in the schematic view 104 of the pair P2 illustrated in FIG. 1, even when the quantum dot QD1 and the quantum dot QD2 are close to each other, the region K can exist, and the first inorganic material 4 fills the region K.

“The first inorganic material 4 fills the space between the quantum dots” need not necessarily refer to that the entire region K between the quantum dot QD1 and the quantum dot QD2 is made of the first inorganic material 4. For example, a material such as an organic material different from the first inorganic material 4 may be included in the region K between the quantum dot QD1 and the quantum dot QD2. Specifically, for example, a carbon element may be contained less than 5 atomic % in the region K.

The first inorganic material 4 may fill a region other than the plurality of quantum dots in the quantum dot layer 33. For example, outer edges (upper face and lower face) of the quantum dot layer 33 may be covered with the first inorganic material 4. Alternatively, there may be a portion of the first inorganic material 4 from the outer edge of the quantum dot layer 33, and the quantum dots may be located away from the outer edge. The outer edge of the quantum dot layer 33 need not be formed only by the first inorganic material 4, and some of the quantum dots may be exposed from the first inorganic material 4. The first inorganic material 4 may be indicated as a portion of the quantum dot layer 33 excluding the plurality of quantum dots.

The first inorganic material 4 may include the plurality of quantum dots. The first inorganic material 4 may be formed so as to fill spaces formed between the plurality of quantum dots. The plurality of quantum dots may be embedded in the first inorganic material 4 at intervals.

The first inorganic material 4 may include a continuous film having an area of 1000 nm² or more in a plane direction orthogonal to a film thickness direction. The continuous film may be a film that is not separated by a material other than a material constituting the continuous film in one plane. The continuous film may be in a form of an integral film connected without interruption by chemical bonding of the first inorganic material 4.

The first inorganic material 4 may be the same material as the shell included in each of the plurality of quantum dots. In this case, an average distance between cores adjacent to each other (core-to-core distance) may be 3 nm or more. Alternatively, the average distance between cores adjacent to each other may be 0.5 times or more an average core diameter. The core-to-core distance is obtained by averaging the shortest distances between 20 adjacent cores. The core-to-core distance may be kept wider than the distance when the shells are in contact with each other. The average core diameter is obtained by averaging the core diameters of 20 adjacent cores in the cross-sectional observation. The core diameter can be the diameter of a circle having the same area as the core area in the cross-sectional observation.

The concentration of the first inorganic material 4 in the quantum dot layer 33 is, for example, an area ratio occupied by the first inorganic material 4 in a cross-section of the quantum dot layer 33. This concentration may be 10% or more and 90% or less, or 30% or more and 70% or less in the cross-sectional observation. The concentration may be measured, for example, from an area ratio of an image obtained in the cross-sectional observation. When the quantum dots have the core/shell structure, the concentration of the shell may be 1% or more and 50% or less. The ratio of the core and the shell of the quantum dot QD and the first inorganic material 4 may be adjusted so that the total is 100% or less as appropriate. When the shell and the first inorganic material 4 cannot be distinguished from each other, the shell may be part of the first inorganic material 4.

The quantum dot layer 33 may be composed of the plurality of quantum dots and the first inorganic material 4. The intensity of carbon detected by a chain structure of carbon when the quantum dot layer 33 is analyzed may be equal to or less than noise level.

It is desirable that the constituent material of the first inorganic material 4 have a wider band gap than the constituent material (for example, the core material) of the quantum dots. As the constituent material of the first inorganic material 4, a semiconductor or an insulator can be used. Examples of the constituent material of the first inorganic material 4 include, for example, a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is desirably stoichiometry in which the actual composition of the compound is the same as the chemical formula but is not necessarily stoichiometry.

The structure of the first inorganic material 4 described above need not be observed over the entire area of the quantum dot layer 33 as long as the structure described above is obtained by observing the cross-section of the quantum dot layer 33 in the range of about 100 nm. The first inorganic material 4 may contain a substance different from a main material which is, for example, an inorganic substance such as an inorganic semiconductor, for example, as an additive.

The first inorganic material 4 strongly protects the surfaces of the quantum dots by filling the space between the quantum dots with the first inorganic material 4. Accordingly, the display device 1, can increase the reliability of the light-emitting element included therein and suppress a decrease in luminance with respect to the driving time of the light-emitting element.

### Addendum to Light-Emitting Element Layer

In the light-emitting element layer 3, the anode 31, the hole transport layer 32, the red quantum dot layer 33R, the electron transport layer 34, and the cathode 35 that overlap the red subpixel SPR in a plan view of the substrate 2 form the red light-emitting element 3R. In the light-emitting element layer 3, the anode 31, the hole transport layer 32, the green quantum dot layer 33G, the electron transport layer 34, and the cathode 35 that overlap the green subpixel SPG in a plan view of the substrate 2 form the green light-emitting element 3G. In the light-emitting element layer 3, the anode 31, the hole transport layer 32, the blue quantum dot layer 33B, the electron transport layer 34, and the cathode 35 that overlap the blue subpixel SPB in a plan view of the substrate 2 form the blue light-emitting element 3B.

The configuration of the light-emitting element layer 3 is not limited to the configuration illustrated in FIG. 1. For example, the light-emitting element layer 3 may further include, on the cathode 35, a capping layer for improving a light extraction efficiency from each light-emitting element.

In the present embodiment, each light-emitting element may extract light from the quantum dot layer 33 from the side of an electrode having optical transparency among the anode 31 and the cathode 35. In this case, an electrode on the side opposite to the electrode having optical transparency among the anode 31 and the cathode 35 may have optical reflectivity in order to improve the extraction efficiency of the light from the quantum dot layer 33.

In particular, in the present embodiment, when each light-emitting element extracts light from the quantum dot layer 33 from the electrode formed on the substrate 2 side among the anode 31 and the cathode 35, that is, from the anode 31 side in the present embodiment, the substrate 2 may have optical transparency.

The light-emitting element layer 3 according to the present embodiment includes the anode 31, on the substrate 2 side, among the anode 31 and the cathode 35 but the embodiment is not limited thereto. For example, the light-emitting element layer 3 may include the cathode 35, the electron transport layer 34, the inorganic layer 5, the quantum dot layer 33, the hole transport layer 32, and the anode 31 in this order on the substrate 2. In this case, the cathode 35 may be formed in an island shape for each subpixel, and each cathode 35 may be electrically connected to the pixel circuit of the substrate 2. The anode 31 may be formed in common to the plurality of subpixels.

### Inorganic Layer

The inorganic layer 5 is located at least between the plurality of light-emitting elements. In the present embodiment, the inorganic layer 5 is formed in common to the plurality of subpixels in particular between the hole transport layer 32 and the electron transport layer 34. Thus, part of the inorganic layer 5 is located between the anode 31 and the cathode 35 of each light-emitting element.

Thus, as described with reference to FIG. 3, part of the inorganic layer 5 is formed at a position overlapping the periphery of the quantum dot layer 33 in a plan view of the substrate 2. In addition, part of the inorganic layer 5 is formed at a position overlapping the anode 31 and the quantum dot layer 33 in a plan view of the substrate 2.

A second inorganic material contained in the inorganic layer 5 includes a semiconductor having a band gap of 2.8 eV or more or an insulator. Chemical formulae of materials that can be employed as the second inorganic material are summarized in the following table.

TABLE 1

| | BAND | | BAND | | BAND |
|---|---|---|---|---|---|
| CHEMICAL | GAP | CHEMICAL | GAP | CHEMICAL | GAP |
| FORMULA | (eV) | FORMULA | (eV) | FORMULA | (eV) |
| BeO | 5.2-14.5 | ZnO | 3.3-3.4 | BaO | 3.8-5.1 |
| BeS | 4.2 | GaO | 4.4-4.5 | CeO₂ | 5.5 |
| B₂O₃ | 4.9-7 | Ga₂S₃ | 3.6 | Nd₂S | 3 |
| MgO | 7.4-7.8 | GeO₂ | 5.5-6 | Sm₂S₃ | 3 |
| MgS | 4.5 | GeS₂ | 3.5 | SmS | 3.2 |
| Al₂O₃ | 7-9.9 | As₂O₃ | 4-5 | EuO | 4.3 |
| Al₂S₃ | 4.1 | SrO | 5.7 | EuS | 3.1 |
| SiO₂ | 8-11 | Y₂O₃ | 5.6 | Dy₂S₃ | 2.9 |
| CaO | 6.1-7.7 | ZrO₂ | 5 | HfO₂ | 5.6 |
| CaS | 5.8 | Nb₂O₅ | 3.5 | HfS₂ | 2.9 |
| Sc₂O₃ | 5.4-6 | MoO₃ | 2.8-3.7 | HfS₃ | 2.9 |
| TiO₂ | 3.8 | In₂O₃ | 2.8-3.8 | Ta₂O₅ | 4.6 |
| MnO | 3.7 | SnO₂ | 4.3 | WO₃ | 2.9 |
| MnS | 6-6.2 | SnS₂ | 2.9 | PbO | 2.9-3.4 |
| NiO | 3.7-4 | Sb₂O₃ | 3.2-4.2 | Bi₂O₃ | 2.9 |
| ZnS | 3.6-3.9 | TeO₂ | 3 | ThO₂ | 3.3-5.8 |

In the above table, the column of “chemical formula” indicates the chemical formulae of the materials that can be employed as the second inorganic material, and “band gap (eV)” indicates a typical band gap of the material represented by the chemical formula in the unit of eV. However, with respect to a material having a range in a band gap such that the band gap varies depending on the composition or the like although the material has the same chemical formula, a lower limit value and an upper limit value of the typical band gap are described in the column of the “band gap (eV)”.

In particular, the inorganic layer 5 may have the same configuration regardless of the position in a plan view of the substrate 2. In other words, the inorganic layer 5 may contain the second inorganic material at any position of the display device 1 in a plan view of the substrate 2.

The inorganic layer 5 according to the present embodiment, is in contact with, in particular, both the hole transport layer 32 and the electron transport layer 34. In this case, the band gap of the second inorganic material may be equal to or larger than the band gap of the charge transport layer with which the inorganic layer 5 is in contact, that is, at least one of the hole transport layer 32 or the electron transport layer 34 in the present embodiment. Furthermore, the band gap of the second inorganic material may have a difference of 0.2 eV or more from the band gap of at least one of the hole transport layer 32 or the electron transport layer 34.

In the present embodiment, the inorganic layer 5 is formed on the substrate 2 side with respect to the quantum dot layer 33, in other words, on the anode 31 side with respect to the quantum dot layer 33, but the embodiment is not limited thereto. For example, the inorganic layer 5 may be formed on the opposite side to the substrate 2 with respect to the quantum dot layer 33, in other words, on the cathode 35 side with respect to the quantum dot layer 33.

### Bank

Furthermore, the display device 1 includes the banks 6. The banks 6 partition the plurality of light-emitting elements included in the display device 1. The bank 6 is an insulating layer having visible light absorption properties or light blocking properties. The banks 6 are formed on the substrate 2, in particular, formed between the plurality of anodes 31 in a plan view of the substrate 2. The banks 6 may be formed at positions overlapping end portions of the anodes 31 in a plan view of the substrate 2. In this case, the bank 6 can reduce the influence of the electric field concentration at the end portion of the anode 31 in each light-emitting element on an injection of holes from the anode 31 to the quantum dot layer 33. Examples of a material of the bank 6 include a photosensitive resin to which a light absorption agent such as carbon black is added. Examples of the above-described photosensitive resin include an organic insulating material such as polyimide and an acrylic resin.

### Leakage Current Reduction

The display device 1 according to the present embodiment includes the plurality of light-emitting elements each containing the quantum dots that include the plurality of quantum dots and the first inorganic material, and the inorganic layer 5 located between the plurality of light-emitting elements. The inorganic layer 5 contains a second inorganic material including a semiconductor having a band gap of 2.8 eV or more or an insulator.

In general, a material used for the quantum dot of the light-emitting element has a band gap approximately corresponding to a light emission wavelength of the quantum dot. That is, the band gap [eV] of the material of the quantum dot approximately has a value obtained by dividing 1240 [eV·nm] by the light emission wavelength [nm]. For example, when the red quantum dot QDR having a light emission wavelength 620 nm is used, the band gap of the red quantum dot QDR is 2.0 eV. When the green quantum dot QDG having a light emission wavelength 530 nm is used, the band gap of the green quantum dot QDG is 2.3 eV. When the blue quantum dot QDB having a light emission wavelength 450 nm is used, the band gap of the blue quantum dot QDB is 2.8 eV. The band gap of the quantum dot described above may be a band gap of a material of a light-emitting portion of the quantum dot including the core of the core/shell quantum dot, or may be a band gap of a material of a non-emitting portion of the quantum dot including the shell.

When the band gap of the inorganic layer 5 is smaller than the band gap of the quantum dot, a current flows through the inorganic layer 5 before a current is injected into the quantum dot, so that an effect of preventing a leakage current is not achieved. On the other hand, when the band gap of the inorganic layer 5 is larger than the band gap of the quantum dot, it can be said that a current does not easily flow through the inorganic layer 5 at a voltage at which a current is injected into the quantum dot, so that the band gap of the inorganic layer 5 is preferably larger than the band gap of the quantum dot. That is, the band gap of the second inorganic material is preferably 2.8 eV or more.

Thus, the inorganic layer 5 can reduce the holes injected from the anode 31 from bypassing the quantum dot layer 33 via the inorganic layer 5 and flowing to the cathode 35 side. Thus, the display device 1, can reduce, by the inorganic layer 5, the occurrence of a leakage current between the anode 31 and the cathode 35 and suppress a decrease in a luminous efficiency of each light-emitting element.

In the present embodiment, the band gap of the second inorganic material is, for example, equal to or larger than the band gap of at least one of the hole transport layer 32 or the electron transport layer 34. Furthermore, the band gap of the second inorganic material has a band gap, for example, having a difference of 0.2 eV or more from the band gap of at least one of the hole transport layer 32 or the electron transport layer 34. Accordingly, the display device 1 can reduce carriers from bypassing the quantum dot layer 33 via the inorganic layer 5 and moving between the hole transport layer 32 and the electron transport layer 34 in each light-emitting element. Thus, the display device 1 further reduce, by the inorganic layer 5, the occurrence of the leakage current between the anode 31 and the cathode 35d.

The film thickness of the inorganic layer 5 may be, for example, 1 nm or more and 30 nm or less. When the film thickness of the inorganic layer 5 is 1 nm or more, the display device 1 sufficiently reduces the occurrence of the leakage current via the inorganic layer 5 and more reliably achieves the effect of improving film formability of the quantum dot layer 33. When the film thickness of the inorganic layer 5 is 30 nm or less, efficiency of an injection of carriers into the quantum dot layer 33 via the inorganic layer 5 is improved, and the resistance of the entire light-emitting element can be reduced. From the viewpoint of further reducing the resistance of the entire light-emitting element, the film thickness of the inorganic layer 5 may be 2 nm or less.

In particular, the inorganic layer 5 may contain aluminum oxide as the second inorganic material. For example, the second inorganic material may contain alumina (Al₂O₃) as aluminum oxide. As shown in the above table, alumina (Al₂O₃) has a relatively large band gap of from 7 eV to 9.9 eV. As described above, when the inorganic layer 5 contains aluminum oxide having a large band gap as the second inorganic material, the display device 1 can further reduce, by the inorganic layer 5, the occurrence of the leakage current.

In general, the mobility of electrons is higher than the mobility of holes in the first inorganic material 4 filling the spaces between the plurality of quantum dots in the quantum dot layer 33. Thus, in the light-emitting element according to the present embodiment, a concentration of electrons in the quantum dot layer 33 tends to be higher than a concentration of holes. Thus, when the light-emitting element layer 3 includes the cathode 35, the electron transport layer 34, the inorganic layer 5, the quantum dot layer 33, the hole transport layer 32, and the anode 31 in this order on the substrate 2, the inorganic layer 5 suppresses an injection of electrons into the quantum dot layer 33 in each light-emitting element. Thus, when the light-emitting element layer 3 has the above-described configuration, the display device 1 suppresses excess of electrons in the quantum dot layer 33 and further improves the luminous efficiency and reliability of each light-emitting element.

### Manufacturing Method of Display Device: Outline

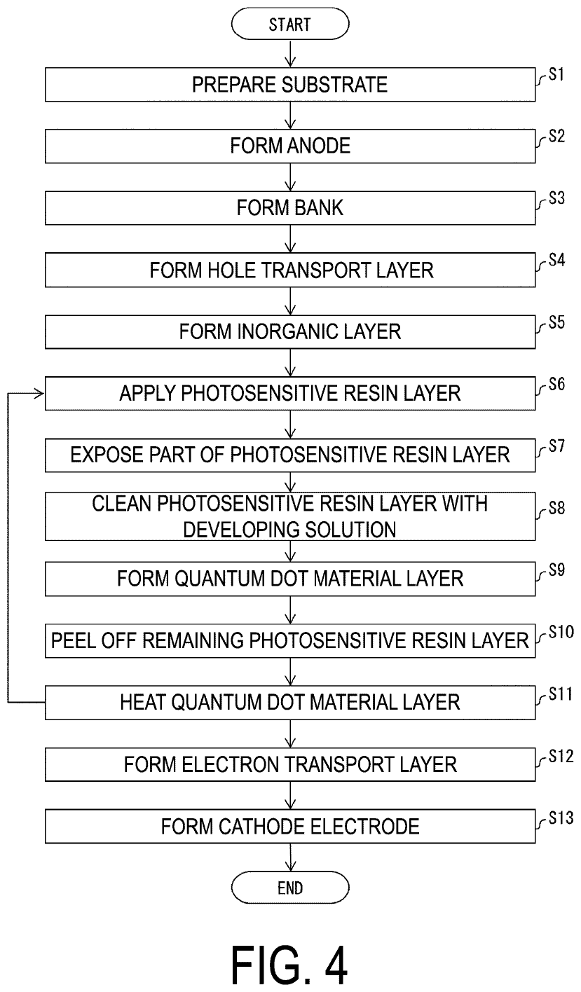

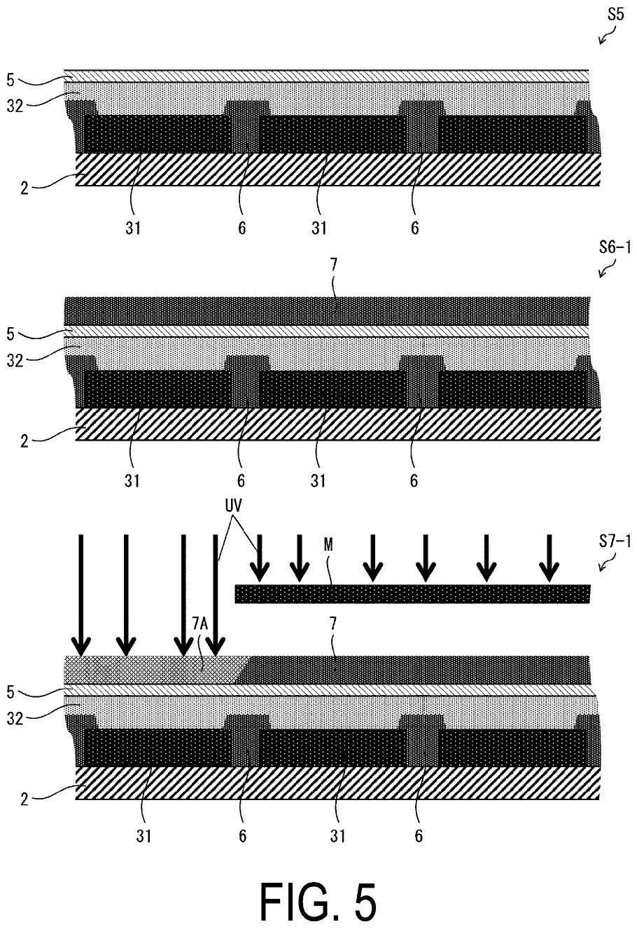

A manufacturing method of the display device 1 according to the present embodiment will be described in detail with reference to FIGS. 4 to 9. FIG. 4 is a flowchart for describing the manufacturing method of the display device 1 according to the present embodiment. FIG. 5 to FIG. 9 are process cross-sectional views illustrating some processes of the manufacturing method of the display device 1 according to the present embodiment. In particular, FIGS. 5 to 9 illustrate cross-sections at the same position as the cross-section illustrated in the schematic cross-sectional side view 101 of the display device 1 illustrated in FIG. 1.

### Manufacturing Method of Display Device: From Preparation of Substrate to Formation of Inorganic Layer

When referring to FIG. 4, in the manufacturing method of the display device according to the present embodiment, first, the substrate 2 is prepared (step S1). In the present embodiment, for example, the substrate 2 including the pixel circuit for each subpixel may be manufactured by forming a thin film transistor for each subpixel on a glass substrate, a film substrate, or the like. Further, the frame portion NA may be formed by forming a driver or the like in the peripheral portion of the substrate 2.

Next, the anode 31 is formed on the substrate 2 (step S2). The anode 31 may be formed by, for example, performing a film formation of a thin film of a metal material or the like on the substrate 2 by sputtering, vacuum deposition, or the like, and then patterning the thin film by dry etching or wet etching.

Next, the banks 6 are formed on the substrate 2 and the anodes 31 (step S3). The banks 6 may be formed by, for example, applying a photosensitive resin to form a film on the substrate 2 and the anodes 31, and then patterning the film by photolithography.

Next, the hole transport layer 32 is formed on the anodes 31 and the banks 6 (step S4). The hole transport layer 32 may be formed by, for example, applying a material having hole transport properties to form a film on the anodes 31 and the banks 6.

Next, the inorganic layer 5 is formed on the hole transport layer 32 (step S5). The inorganic layer 5 may be formed from, for example, an application material containing a precursor of the second inorganic material. In this case, for example, the second inorganic material may be formed from the precursor in the application material by applying the application material to form a film on the hole transport layer 32 and then heating the application material. For example, ZnS can be formed as the second inorganic material by alternately applying solutions containing Zn²⁺ and S²⁻, such as potassium sulfide (solvent: ethanol) and zinc chloride (solvent: ethanol), about 10 times. In this step, the quantum dots are not necessarily dispersed in the solution, and thus ethanol (dielectric constant: 25) can be used, ethanol having a low polarity (low relative dielectric constant) and good application properties as compared with a solvent used for forming the quantum dot layer described later. In step S5, baking may be performed to volatilize the solvent in the application material. As described above, a layered body from the substrate 2 to the inorganic layer 5 illustrated in step S5 of FIG. 5 is obtained. The forming method of the inorganic layer 5 is not limited to this as long as the inorganic layer 5 is formed between the plurality of light-emitting elements. For example, in a forming process of the inorganic layer 5, the inorganic layer 5 may be formed only at a desired position by patterning by a lift-off method or the like using photolithography.

Manufacturing Method of Display Device: Formation of Quantum Dot Layer Next, the quantum dot layer 33 is formed. In the present embodiment, in the forming process of the quantum dot layer 33, an example of a method of forming the red quantum dot layer 33R, the green quantum dot layer 33G, and the blue quantum dot layer 33B in this order will be described.

In the forming process of the quantum dot layer 33, for example, first, a photosensitive resin layer 7 is formed (step S6). For example, as illustrated in step S6-1 of FIG. 5, the photosensitive resin layer 7 is formed by applying a photosensitive resin to form a film on the inorganic layer 5. Here, in the present embodiment, an example will be described in which the photosensitive resin layer 7 contains a positive photosensitive resin.

After step S6, part of the applied photosensitive resin layer 7 is exposed. In step S7 of the forming process of the red quantum dot layer 33R, for example, as illustrated in step S7-1 of FIG. 5, a mask M that blocks ultraviolet rays and includes a transmitting portion such as an opening that transmits ultraviolet rays is installed at a position corresponding to the red subpixel SPR. Next, the photosensitive resin layer 7 is irradiated with ultraviolet rays UV from above the mask M. Accordingly, as illustrated in step S7-1 of FIG. 5, only a portion of the photosensitive resin layer 7 located at the position corresponding to the red subpixel SPR is irradiated with the ultraviolet rays UV, and the portion becomes an exposed portion 7A.

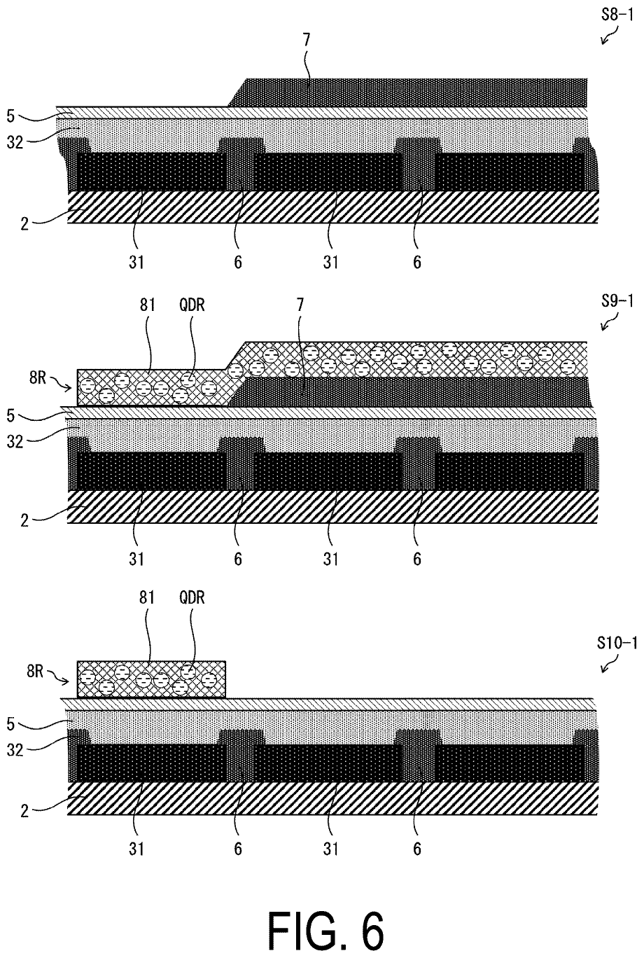

After step S7, the photosensitive resin layer 7 including the exposed portion 7A is cleaned with an appropriate developing solution (step S8). In this case, for example, as the developing solution, a developing solution to which unexposed photosensitive resin layer 7 is hardly soluble and the exposed portion 7A is highly soluble is used. The developing solution may be, for example, an alkaline solution containing TMAH or the like. Accordingly, for example, as illustrated in step S8-1 of FIG. 6, the photosensitive resin layer 7 is peeled off only from the position corresponding to the red subpixel SPR.

After step S8, a quantum dot material layer is formed (step S9). In step S9 of the forming process of the red quantum dot layer 33R, for example, as illustrated in step S9-1 of FIG. 6, a red quantum dot material layer 8R is applied to form a film on the photosensitive resin layer 7 and on the inorganic layer 5 exposed by peeling off the photosensitive resin layer 7. The red quantum dot material layer 8R is, for example, a layer formed by applying an application material obtained by mixing the plurality of red quantum dots QDR and a solution in which a precursor 81 of the first inorganic material 4 is dispersed. As the application material, for example, ZnS as the first inorganic material, thiourea zinc or the like as the precursor 81 of the first inorganic material, and N,N-dimethylformamide (DMF, relative dielectric constant 37) or the like as the solvent can be used. In order to disperse the quantum dots in the solvent of the application material, a highly polar (having a large relative dielectric constant) solvent is preferably used. In general, in the case of the highly polar solvent, the wettability on the hydrophobic organic hole transport layer is poor, and uniform application is difficult. However, by forming the hydrophilic inorganic layer 5 in advance, the wettability can be improved, and a uniform quantum dot material layer can be formed.

After step S9, the remaining photosensitive resin layer 7 is peeled off (step S10). The peeling off of the photosensitive resin layer 7 may be performed by, for example, cleaning the photosensitive resin layer 7 with an organic solvent such as PGMEA. Here, in step S10, a material to which the inorganic layer 5 and materials other than the photosensitive resin layer 7 on the inorganic layer 5 are not dissolved is employed.

Accordingly, in step S10 of the forming process of the red quantum dot layer 33R, the red quantum dot material layer 8R located on the photosensitive resin layer 7 is removed together with the peeling of the photosensitive resin layer 7. Thus, for example, as illustrated in step S10-1 of FIG. 6, the red quantum dot material layer 8R remains only at the position corresponding to the red subpixel SPR.

After step S10, the quantum dot material layer is heated at a high temperature (step S11). In step S11, for example, the quantum dot layer may be heated in a 250° C. atmosphere for 30 minutes. Accordingly, for example, in step S11 of the forming process of the red quantum dot layer 33R, the precursor 81 in the red quantum dot material layer 8R reacts to form the first inorganic material 4.

Here, the precursor 81 in the red quantum dot material layer 8R is sequentially formed around the red quantum dots QDR in the red quantum dot material layer 8R by heating in step S11. Thus, the first inorganic material 4 is formed by step S11 so as to fill the spaces between the plurality of red quantum dots QDR.

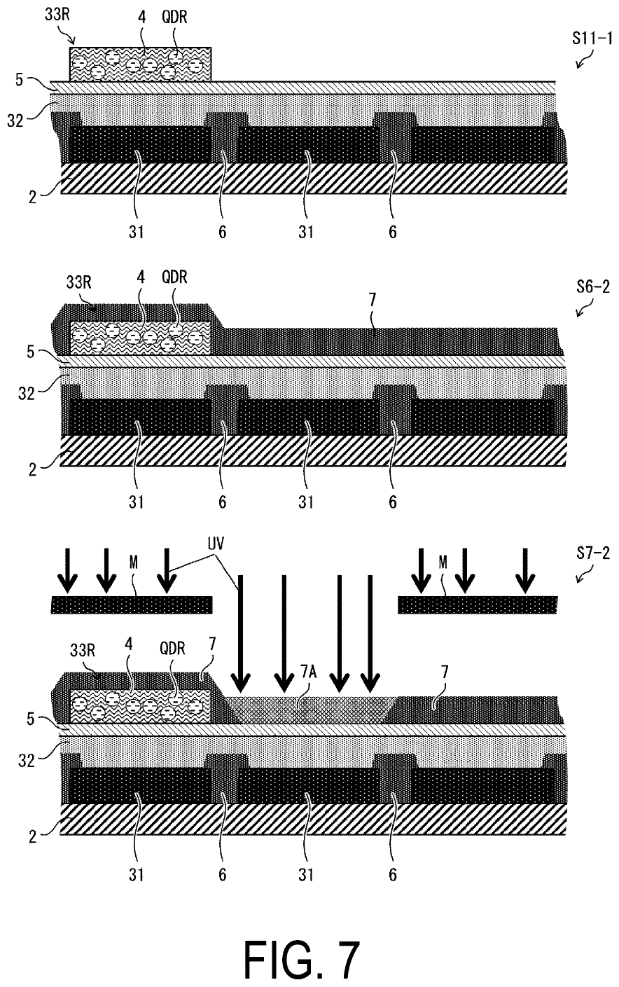

As described above, as illustrated in step S11-1 of FIG. 7, the red quantum dot layer 33R is formed at the position corresponding to the red subpixel SPR on the inorganic layer 5.

The above-described steps S6 to S11 are repeatedly executed until quantum dot layers of all luminescent colors are formed. For example, in the present embodiment, a forming process of the green quantum dot layer 33G is executed subsequent to the forming process of the red quantum dot layer 33R.

For example, in step S6 of the forming process of the green quantum dot layer 33G, as illustrated in step S6-2 of FIG. 7, the photosensitive resin layer 7 is formed on the formed red quantum dot layer 33R in addition to the inorganic layer 5. The red quantum dots QDR in the red quantum dot layer 33R are protected by the first inorganic material 4, and thus the first inorganic material 4 can reduce the influence of the photosensitive resin layer 7 on the red quantum dots QDR.

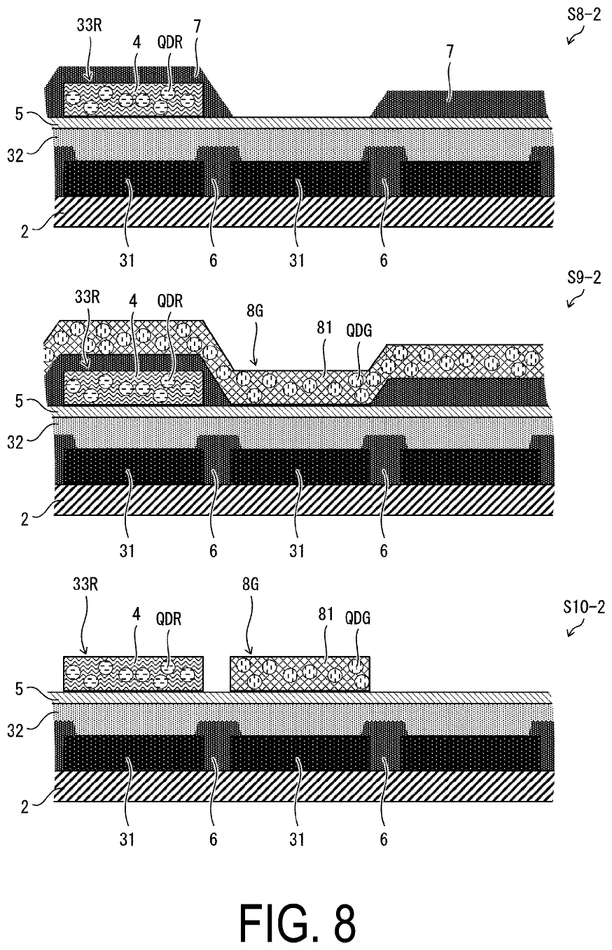

For example, in step S7 of the forming process of the green quantum dot layer 33G, as illustrated in step S7-2 of FIG. 7, a portion of the photosensitive resin layer 7 at a position corresponding to the green subpixel SPG is the exposed portion 7A. Thus, in the subsequent step S8, as illustrated in step S8-2 of FIG. 8, the photosensitive resin layer 7 is peeled off only from the position corresponding to the green subpixel SPG.

In step S9 of the forming process of the green quantum dot layer 33G, as illustrated in step S9-2 of FIG. 8, a film formation of the green quantum dot material layer 8G in which the green quantum dot QDG is mixed in the precursor 81 is performed. In step S10 of the forming process of the green quantum dot layer 33G, as illustrated in step S10-2 of FIG. 8, the green quantum dot material layer 8G remains only at the position corresponding to the green subpixel SPG. The red quantum dots QDR in the red quantum dot layer 33R are protected by the first inorganic material 4, and thus the first inorganic material 4 can reduce the influence of a peeling process of the photosensitive resin layer 7 in step S10 on the red quantum dots QDR.

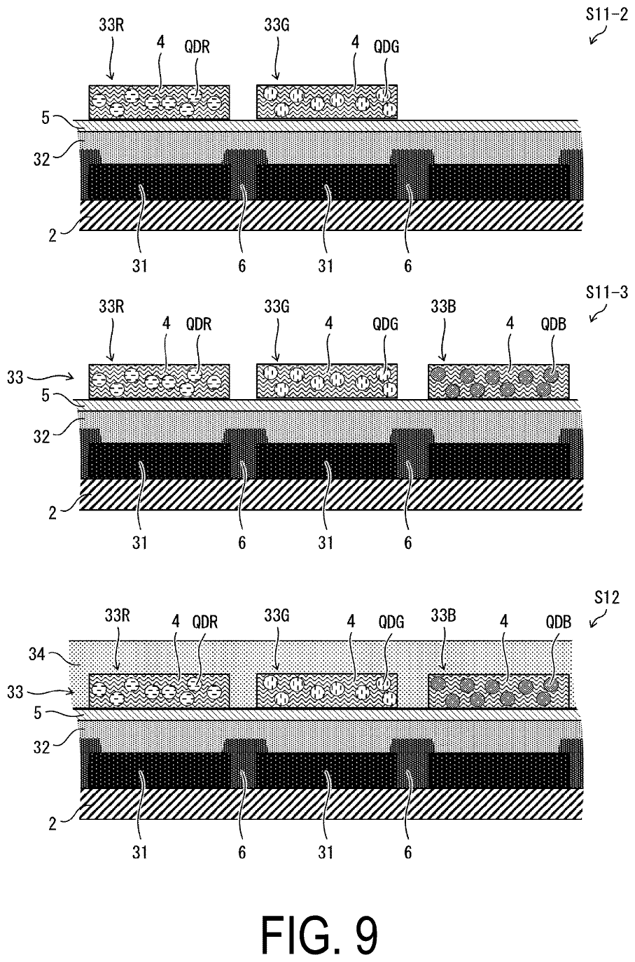

In step S11 of the forming process of the green quantum dot layer 33G, as illustrated in step S11-2 of FIG. 9, by heating the green quantum dot material layer 8G, the green quantum dot layer 33G is formed at the position corresponding to the green subpixel SPG on the inorganic layer 5. Also in step S11 of the forming process of the green quantum dot layer 33G, the red quantum dots QDR in the red quantum dot layer 33R are protected by the first inorganic material 4. Thus, according to the manufacturing method of the display device 1 according to the present embodiment, deterioration of the red quantum dots QDR caused by heating of the green quantum dot material layer 8G can be reduced.

Subsequently, in the same manner as described above, as illustrated in step S11-3 of FIG. 9, by executing step S6 to step S11, the blue quantum dot layer 33B is formed at a position corresponding to the blue subpixel SPB on the inorganic layer 5. As a result, the quantum dot layer 33 is formed. Also in the forming process of the blue quantum dot layer 33B, the red quantum dots QDR and the green quantum dots QDG are protected by the first inorganic material 4. Thus, the first inorganic material 4 can reduce the influence of the forming process of the blue quantum dot layer 33B on the red quantum dots QDR and the green quantum dots QDG.

As described above, in the example of the manufacturing method of the display device 1 according to the present embodiment, the quantum dot material layer formed in common to the plurality of subpixels is patterned to form the quantum dot layers 33. Here, as described above, in the patterning of the quantum dot material layer, all the quantum dots in the quantum dot layer 33 that have already been formed are protected by the first inorganic material 4. Thus, according to the method of manufacturing the display device 1 according to the present embodiment, by patterning the quantum dot material layer, deterioration of the quantum dots in the quantum dot layer 33 due to the patterning can be reduced while the quantum dot layer 33 for each subpixel can be more easily formed.

Here, for example, an organic material may be employed for the hole transport layer 32 in order to further improve the hole injection efficiency. In this case, when the quantum dot material layer containing the precursor 81 of the first inorganic material 4 is applied onto the hole transport layer 32 which is a layer of the organic material, the film formability of the quantum dot material layer may be deteriorated, and the quality of the quantum dot layer 33 including uniformity of the film thickness of the quantum dot layer 33 may be reduced.

In the example of the manufacturing method of the display device 1 according to the present embodiment, the quantum dot layer 33 is formed on the inorganic layer 5. The film formability of the quantum dot material layer on the inorganic layer 5 containing the second inorganic material is improved more than the film formability of the quantum dot material layer on the hole transport layer 32 containing the organic material. Thus, according to the manufacturing method of the display device 1 according to the present embodiment, the quality of the quantum dot layer 33 including the uniformity of the film thickness of the quantum dot layer 33 is improved.

For example, the first inorganic material 4 and the second inorganic material may contain the same inorganic material. In this case, the film formability of the quantum dot material layer in step S9 is improved. When the first inorganic material 4 and the second inorganic material are made of the same inorganic material, a lower face of each quantum dot layer may be a straight line (common tangent line) connecting lowermost portions of the plurality of quantum dots of the quantum dot layer and may be a boundary between the inorganic layer 5 and each quantum dot.

Furthermore, for example, the first inorganic material 4 and the second inorganic material may contain zinc sulfide (ZnS) or zinc magnesium sulfide (ZnMgS, ZnMgS₂). In this case, the film formability of the quantum dot material layer in step S9 is improved, and the effect of protecting the quantum dots by the first inorganic material 4 can be enhanced.

Manufacturing Method of Display Device: after Formation of Electron Transport Layer After the formation of the quantum dot layer 33, the electron transport layer 34 is formed on the inorganic layer 5 and the quantum dot layer 33 (step S12). The electron transport layer 34 may be formed by, for example, applying a material having electron transport properties to form a film on the inorganic layer 5 and the quantum dot layer 33. Accordingly, as illustrated in step S12 of FIG. 9, the electron transport layer 34 is formed such that the electron transport layer 34 is in contact with the inorganic layer 5 and the quantum dot layer 33 but is not in direct contact with the hole transport layer 32.

In step S12, the electron transport layer 34 may be formed on side surfaces of the red quantum dot layer 33R, the green quantum dot layer 33G, and the blue quantum dot layer 33B and also between these side surfaces. Accordingly, in step S12, the electron transport layer 34 for partitioning the red quantum dot layer 33R, the green quantum dot layer 33G, and the blue quantum dot layer 33B for each subpixel may be formed.

Next, the cathode 35 is formed on the electron transport layer 34 (step S13). The cathode 35 may be formed by, for example, performing a film formation of a thin film of a metal material or the like on the electron transport layer 34 by sputtering or the like. Note that, as an upper layer of the cathode 35, a sealing layer (not illustrated) may be formed in order to prevent infiltration of foreign matters, such as moisture, oxygen, and excess organic matters such as dust generated during a manufacturing process, into the light-emitting element. Further, as an upper layer above the sealing layer, for example, a function layer having at least one of an optical compensation function, a touch sensor function, or a protection function, a touch panel, a polarizer, or the like may be formed as necessary. As described above, the light-emitting element layer 3 exemplified in FIG. 1 is formed on the substrate 2, and the manufacturing process of the display device 1 is completed.

The manufacturing method of the display device 1 is not limited thereto, and for example, the quantum dot layer 33 may be formed after the hole transport layer 32 is formed, and then the inorganic layer 5 may be formed. In this case, the display device 1 including the plurality of light-emitting elements each including the inorganic layer 5 on the cathode 35 side with respect to the quantum dot layer 33 can be manufactured.

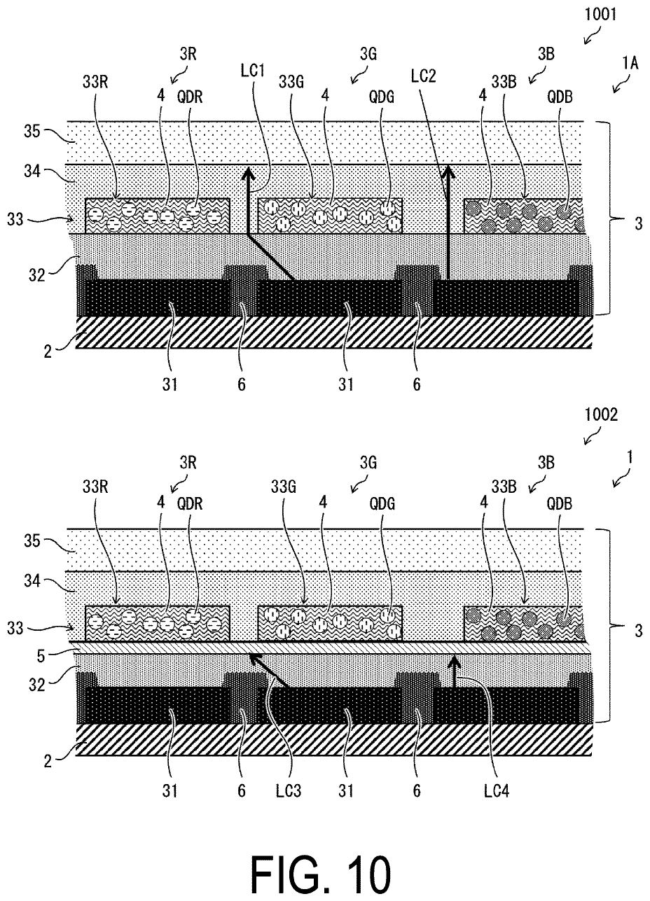

Leakage Current of Display Device according to Comparative Embodiment A mechanism for reducing a leakage current in each light-emitting element of the display device 1 according to the present embodiment will be described in comparison with a display device according to a comparative embodiment. FIG. 10 is a schematic cross-sectional side view 1001 of a display device 1A according to a first comparative embodiment and a schematic cross-sectional side view 1002 of the display device 1 according to the present embodiment.

FIG. 10 illustrates an example of each display device in a case where an offset occurs in a formation position of the blue quantum dot layer 33B in the manufacturing process of each display device. For example, in step S7 of the manufacturing method of the display device 1 described above, when an installation position of the mask M is offset from an original position, a position of the exposed portion 7A is also offset, and thus a formation position of the quantum dot layer 33 may be offset. The offset of the formation position of the quantum dot layer 33 can occur due to, for example, deformation of the mask M due to generation of stress on the mask M or a change in temperature, or deformation of the substrate 2 due to generation of stress on the substrate 2 or a change in temperature.

In a case of forming the light-emitting layer in which the first inorganic material 4 is filled with the quantum dots, it is necessary to heat a material containing the precursor 81 at a high temperature in order to form the first inorganic material 4 by reacting the precursor 81. In the heating, heat is easily applied to the mask M or the substrate 2, and thus the positional offset of the mask M is likely to occur. In addition, in a high resolution display having a small pixel size, the offset of the mask M with respect to the position of the pixel is relatively large, and thus this problem is likely to occur. Even in such a case, according to the disclosure, the leakage current described below can be effectively reduced and the decrease in the luminous efficiency of each light-emitting element can be suppressed.

In particular, FIG. 10 illustrates an example in which a position where the anode 31 of the blue subpixel SPB and the blue quantum dot layer 33B do not overlap each other in a plan view of the substrate 2 is generated in each display device due to the offset of the formation position of the blue quantum dot layer 33B.

The display device 1A according to the first comparative embodiment does not include the inorganic layer 5 as compared with the display device 1 according to the present embodiment. Thus, the display device 1A includes a portion where the hole transport layer 32 and the electron transport layer 34 are in direct contact with each other. Thus, as illustrated in the schematic cross-sectional side view 1001 of the display device 1A in FIG. 10, a leakage current LC1 may be generated from the anode 31 to the cathode 35 passing through the hole transport layer 32 and the electron transport layer 34 in this order. The leakage current LC1 does not pass through the quantum dot layer 33 and does not contribute to light emission of each light-emitting element, and thus generation of the leakage current LC1 reduces the luminous efficiency of each light-emitting element of the display device 1A.

As described above, in the display device 1A, there is a position where the anode 31 of the blue subpixel SPB and the blue quantum dot layer 33B do not overlap each other in a plan view of the substrate 2. At this position, as illustrated in the schematic cross-sectional side view 1001 of the display device 1A in FIG. 10, a leakage current LC2 may be generated to flow from the anode 31 to the cathode 35 in substantially the same direction as a layering direction of the blue light-emitting element 3B without passing through the quantum dot layer 33. A path of the leakage current LC2 is a substantially shortest path from the anode 31 to the cathode 35, and thus the intensity of the leakage current LC2 tends to be larger than the intensity of the leakage current LC1. Thus, when an offset occurs in the formation position of the quantum dot layer 33 in the manufacturing process of the display device 1A, the luminous efficiency of each light-emitting element of the display device 1A may be further reduced.

### Mechanism for Reducing Leakage Current

On the other hand, the display device 1 according to the present embodiment includes the inorganic layer 5, and thus the display device 1 does not include a portion where the hole transport layer 32 and the electron transport layer 34 are in contact with each other. Thus, as illustrated in the schematic cross-sectional side view 1002 of the display device 1 in FIG. 10, the inorganic layer 5 reduces a leakage current LC3 flowing from the anode 31 to the electron transport layer 34 and the cathode 35 via the hole transport layer 32 by bypassing the quantum dot layer 33.

Furthermore, the band gap of the second inorganic material contained in the inorganic layer 5 is 2.8 eV or more. Thus, for the above-described reason, the display device 1 can make the intensity of the current flowing to the quantum dot layer 33 via the inorganic layer 5 larger than the intensity of the leakage current passing through the inorganic layer 5 and bypassing the quantum dot layer 33.

Thus, the display device 1 reduces the intensity of the generated leakage current and reduces the suppression of the luminous efficiency in each light-emitting element.

Each quantum dot layer according to the present embodiment may be formed on the peripheral side of the position where each anode 31 and the hole transport layer 32 are in contact with each other in a plan view. In this case, by the inorganic layer 5 located between the plurality of light-emitting elements, the display device 1 can reduce the leakage current from flowing to the quantum dot layer formed at the above-described position, and thus can reduce abnormal light emission in which light emission occurs outside the light-emitting element.

The inorganic layer 5 according to the present embodiment is also formed between the anode 31 and the cathode 35 of each light-emitting element. Thus, in the display device 1, even when the position where the anode 31 of the blue subpixel SPB and the blue quantum dot layer 33B do not overlap each other occur in a plan view of the substrate 2, the inorganic layer 5 is formed at the position. Thus, the display device 1 can reduce the intensity of a leakage current LC4 flowing between the anode 31 and the cathode 35 in a substantially shortest path.

Thus, even when an offset occurs in the formation position of the quantum dot layer 33, the display device 1 reduces the intensity of the generated leakage current and suppresses a decrease in the luminous efficiency of each light-emitting element.

For example, the magnitude of a diode current is proportional to an intrinsic carrier density of the semiconductor, in other words, proportional to exp(−E_{g}/kT) where E_{g} is a band gap of the semiconductor. Where k is the Boltzmann constant and T is a temperature of the semiconductor.

Here, it is assumed that ZnO (band gap E_{g}=3.3 eV) which is generally employed as a material of an electron transport layer is employed as a material of the electron transport layer 34. In this case, the leakage current flowing from the hole transport layer 32 to the electron transport layer 34 at the portion where the hole transport layer 32 and the electron transport layer 34 are in contact with each other is proportional to exp(−E_{g}/kT)=2×10⁻²⁸.

On the other hand, it is assumed that ZnS (band gap E_{g}=3.6 eV) is employed as the second inorganic material. In this case, the leakage current flowing from the hole transport layer 32 to the electron transport layer 34 via the inorganic layer 5 at the portion where the hole transport layer 32 and the inorganic layer 5 are in contact with each other is proportional to exp(−E_{g}/kT)=6×10⁻³¹. In this case, the display device 1 according to the present embodiment can reduce the leakage current flowing from the hole transport layer 32 to the electron transport layer 34 by about three orders of magnitude as compared with the case where the inorganic layer 5 is not included.

In addition, it is assumed that a material having a band gap E_{g} of 3.5 eV is employed as the second inorganic material. In this case, the leakage current flowing from the hole transport layer 32 to the electron transport layer 34 via the inorganic layer 5 at the portion where the hole transport layer 32 and the inorganic layer 5 are in contact with each other is proportional to exp(−E_{g}/kT)=4×10⁻³⁰. Also in this case, the display device 1 according to the present embodiment can reduce the leakage current flowing from the hole transport layer 32 to the electron transport layer 34 by about two orders of magnitude as compared with the case where the inorganic layer 5 is not included.

Thus, the band gap of the second inorganic material may be equal to or larger than the band gap of the hole transport layer 32. Furthermore, the band gap of the second inorganic material may have a difference of 0.2 eV or more from the band gap of the hole transport layer 32, or may have a difference of 0.3 eV or more from the band gap of the hole transport layer 32. Accordingly, the display device 1 can improve the efficiency of hole injection from the hole transport layer 32 to the quantum dot layer 33 via the inorganic layer 5 in each light-emitting element, and further reduce the occurrence of the leakage current. From the viewpoint of sufficiently reducing the leakage current flowing from the hole transport layer 32 to the electron transport layer 34, the band gap of the second inorganic material of the inorganic layer 5 may be 3.5 eV or more, or may be 3.6 eV or more.

### Second Embodiment

Inorganic Layer Having Different Thickness Depending on Position Another embodiment of the disclosure will be described below. Further, members having the same functions as those of the members described in the above-described embodiments will be denoted by the same reference numerals and signs, and the description thereof will not be repeated for the sake of convenience of description.

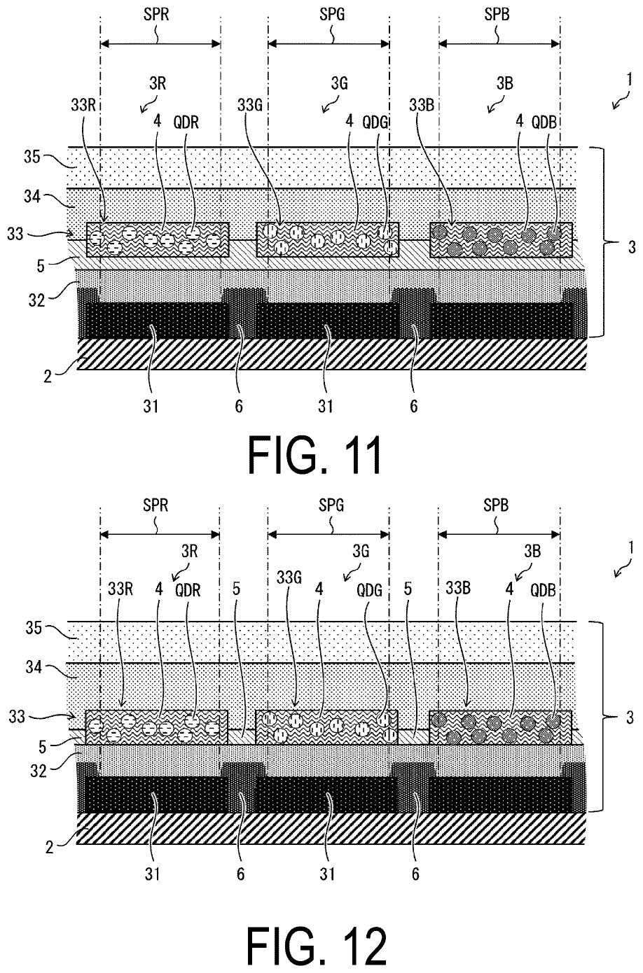

FIG. 11 is a schematic cross-sectional side view of the display device 1 according to the present embodiment. Except for the film thickness of the inorganic layer 5, the display device 1 according to the present embodiment has the same configuration as that of the display device 1 according to the previous embodiment.

The thickness of the inorganic layer 5 according to the present embodiment varies depending on the position in a plan view of the substrate 2. In particular, the thickness of the inorganic layer 5 in contact with the quantum dot layer 33 is smaller than the thickness of the inorganic layer 5 overlapping the periphery of the quantum dot layer 33 in a plan view of the substrate 2.

Thus, the display device 1 according to the present embodiment can further reduce, by the inorganic layer 5, the intensity of the leakage current LC flowing by bypassing the quantum dot layer 33. On the other hand, the display device 1 can maintain the hole injection efficiency from the hole transport layer 32 to the quantum dot layer 33 in each light-emitting element. Thus, the display device 1 can maintain the luminous efficiency of each light-emitting element while reducing the leakage current of each light-emitting element.

The display device 1 according to the present embodiment can be manufactured by the same method as the manufacturing method of the display device 1 described in the previous embodiment by changing only part of step S9. In step S9 of the manufacturing method of the display device 1 according to the present embodiment, the highly polar solvent is used as the solvent to which the plurality of quantum dots and the precursor 81 of the first inorganic material 4 are dispersed, and thus the quantum dot material is dissolved in a solution for applying the inorganic layer 5 when the quantum dot material is applied.

Accordingly, in step S9, a portion of the inorganic layer 5 that is in contact with the quantum dot material layer is dissolved in the solution, and the film thickness of the portion is reduced. In this state, by executing subsequent step S10 and step S11, the quantum dot layer 33 in which part of the quantum dot layer 33 enters the inorganic layer 5 toward the substrate 2 side is formed. Accordingly, the inorganic layer 5 is formed such that the thickness of a portion in contact with the quantum dot layer 33 is smaller than the thickness of a portion overlapping the periphery of the quantum dot layer 33 in a plan view of the substrate 2.

In order to achieve the above-described manufacturing method, the precursor 81 of the quantum dot material layer and the second inorganic material of the inorganic layer 5 may be soluble in each other. The first inorganic material 4 and the second inorganic material may be the same material. In this case, the mutual solubility of the precursor 81 of the quantum dot material layer and the second inorganic material of the inorganic layer 5 can be improved.

According to the above-described manufacturing method, even when the offset of the formation position of the quantum dot layer 33 occurs due to the positional offset of the mask M or the like, only the film thickness of the inorganic layer 5 in contact with the quantum dot layer 33 can be reduced. Accordingly, even when an offset occurs in the formation position of the quantum dot layer 33, the display device 1 according to the present embodiment reduces the intensity of the generated leakage current, and suppresses a decrease in the luminous efficiency of each light-emitting element. In addition, the film thickness of the inorganic layer 5 in contact with the quantum dot layer 33 is small, and thus a current injection into the quantum dot layer 33 can be improved and the luminous efficiency can be increased.

### Third Embodiment

Inorganic Layer Located only between Light-Emitting Elements FIG. 12 is a schematic cross-sectional side view of the display device 1 according to the present embodiment. Except for the formation position of the inorganic layer 5, the display device 1 according to the present embodiment has the same configuration as that of the display device 1 according to the previous each embodiment.

The inorganic layer 5 according to the present embodiment is formed only at the position overlapping the periphery of the quantum dot layer 33 in a plan view of the substrate 2. In other words, the inorganic layer 5 is not formed at the position overlapping the quantum dot layer 33 in a plan view of the substrate 2.

Thus, the display device 1 according to the present embodiment can further reduce, by the inorganic layer 5, the intensity of the leakage current LC flowing by bypassing the quantum dot layer 33. On the other hand, the display device 1 can further improve the hole injection efficiency from the hole transport layer 32 to the quantum dot layer 33 in each light-emitting element. Thus, the display device 1 can improve the luminous efficiency of each light-emitting element while reducing the leakage current of each light-emitting element.

The display device 1 according to the present embodiment can be manufactured by the same method as the manufacturing method of the display device 1 described above by changing only part of step S9. In step S9 of the manufacturing method of the display device 1 according to the present embodiment, further highly polar solvent is used as the solvent to which the plurality of quantum dots and the precursor 81 of the first inorganic material 4 are dispersed, and thus the quantum dot material is dissolved in a solution for applying the inorganic layer 5 when the quantum dot material is applied.

Accordingly, in step S9, the portion of the inorganic layer 5 that is in contact with the quantum dot material layer is dissolved in the solution and disappears, and the quantum dot layer 33 and the hole transport layer 32 are in contact with each other. In this state, by executing the subsequent steps S10 and S11, the quantum dot layer 33 that enters the inorganic layer 5 toward the substrate 2 and is in contact with the hole transport layer 32 is formed. Accordingly, the inorganic layer 5 is formed only in the portion overlapping the periphery of the quantum dot layer 33 in a plan view of the substrate 2.

According to the above-described manufacturing method, even when the offset of the formation position of the quantum dot layer 33 occurs, the inorganic layer 5 can be formed only in the portion overlapping the periphery of the quantum dot layer 33 in a plan view of the substrate 2. Accordingly, even when an offset occurs in the formation position of the quantum dot layer 33, the display device 1 according to the present embodiment reduces the intensity of the generated leakage current, and suppresses a decrease in the luminous efficiency of each light-emitting element. In addition, there is no inorganic layer 5 in contact with the quantum dot layer 33 in the layering direction of the light-emitting element, and thus a current injection into the quantum dot layer 33 can be improved and the luminous efficiency can be increased.

### Fourth Embodiment

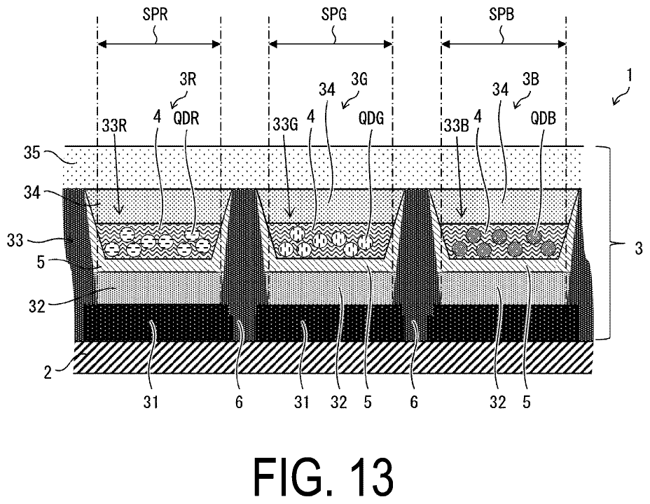

Display Device in which Banks Partition Light-Emitting Elements FIG. 13 is a schematic cross-sectional side view of the display device 1 according to the present embodiment. The display device 1 according to the present embodiment differs in a height of the bank 6 from the substrate 2 as compared with the display device 1 according to the previous each embodiment. In particular, in the present embodiment, the bank 6 is formed from the upper face of the substrate 2 to the lower face of the cathode 35 of the light-emitting element layer 3.

Thus, in addition to the anode 31, the bank 6 partitions the hole transport layer 32, the quantum dot layer 33, and the electron transport layer 34 for each subpixel. In other words, the banks 6 according to the present embodiment partition the plurality of light-emitting elements included in the display device 1.

In the present embodiment, the inorganic layer 5 is also formed on the side surface of the bank 6, and accordingly, the inorganic layer 5 is in contact with the side surfaces of the quantum dot layer 33 and the electron transport layer 34 in each light-emitting element. Thus, at least part of the inorganic layer 5 is located between the electron transport layer 34 and the bank 6.

In the present embodiment, the inorganic layer 5 is partitioned by the bank 6 for each subpixel, but the embodiment is not limited thereto. For example, the inorganic layer 5 may also be formed on an upper face of the bank 6, and accordingly, may be formed in common to the plurality of subpixels.

Except for the above, the display device 1 according to the present embodiment may have the same configuration as the display device 1 according to each embodiment described above. In particular, also in the present embodiment, the inorganic layer 5 contains a second inorganic material including a semiconductor having a band gap of 2.8 eV or more or an insulator. Thus, as illustrated in FIG. 13, even when the inorganic layer 5 is in contact with the side surface of the electron transport layer 34, the display device 1 can reduce the holes injected from the anode 31 from flowing to the electron transport layer 34 and the cathode 35 via the inorganic layer 5. Thus, the display device 1, can reduce, by the inorganic layer 5, the occurrence of a leakage current between the anode 31 and the cathode 35 and suppress a decrease in a luminous efficiency of each light-emitting element.

### Another Example of Manufacturing Method of Display Device

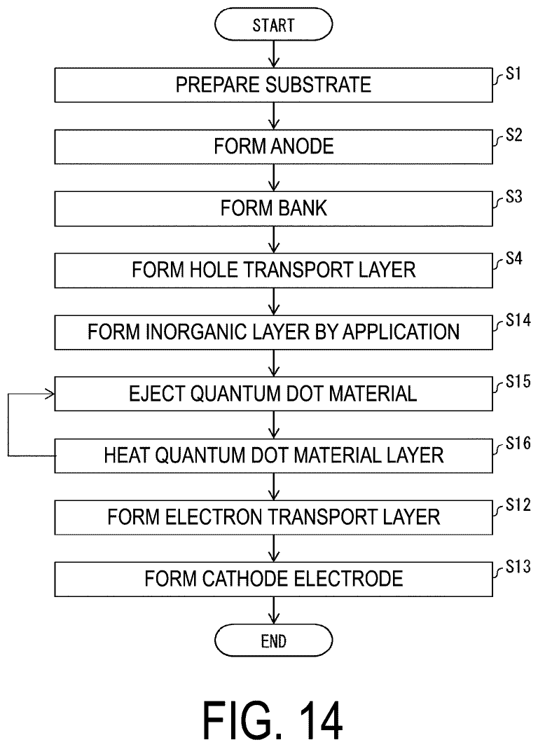

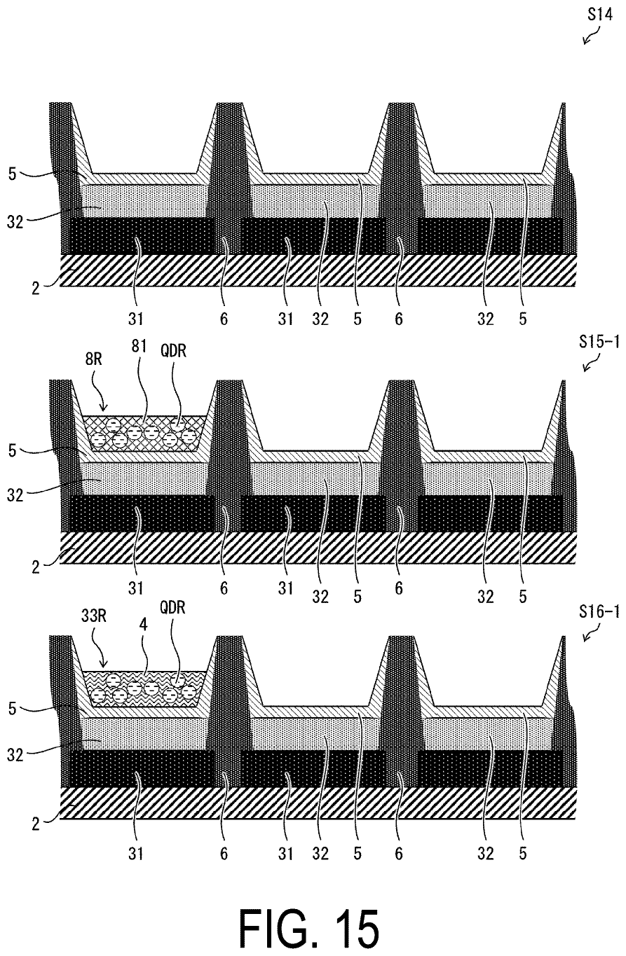

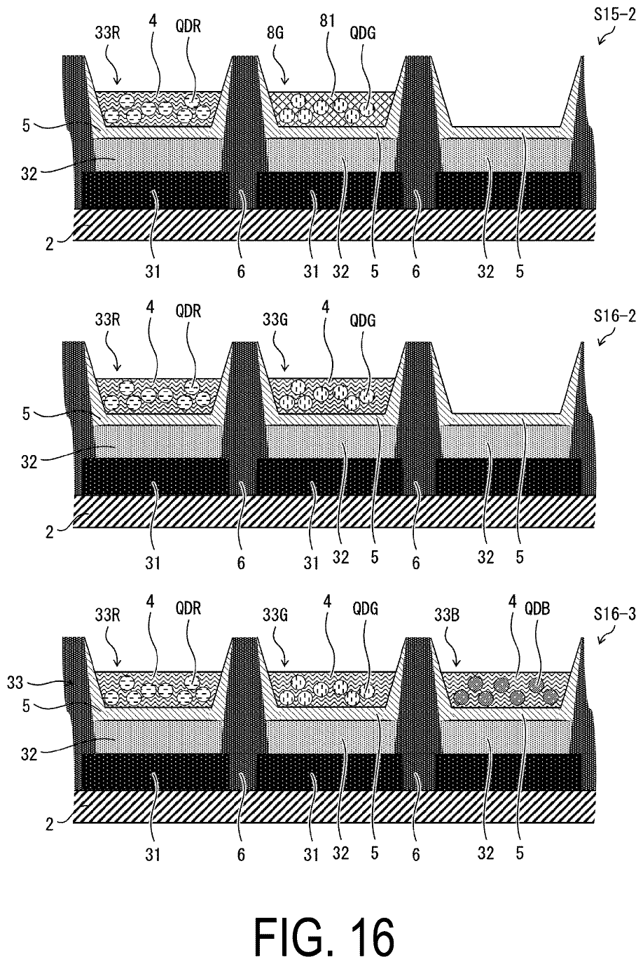

An example of the manufacturing method of the display device 1 according to the present embodiment will be described in detail with reference to FIGS. 14 to 16. FIG. 14 is a flowchart for describing the manufacturing method of the display device 1 according to the present embodiment. FIGS. 15 and 16 are process cross-sectional views illustrating some processes of the manufacturing method of the display device 1 according to the present embodiment. In particular, FIGS. 15 and 16 illustrate cross-sections at the same position as the cross-section illustrated in the schematic cross-sectional side view of the display device 1 illustrated in FIG. 13.

When referring to FIG. 4, in the manufacturing method of the display device according to the present embodiment, first, step S1 to step S4 described above are executed. However, in step S3, the banks 6 that partition the plurality of anodes 31 is formed so that a height of the bank 6 becomes a height at which from the hole transport layer 32 to the electron transport layer 34 of the light-emitting element layer 3 are partitioned by the bank 6 in a later process. In step S4, the hole transport layers 32 may be formed by individually ejecting the material of the hole transport layer 32 onto each anode 31 and between the banks 6 in a plan view of the substrate 2 by an inkjet method or the like. As described above, the anodes 31, the banks 6, and the hole transport layers 32 are formed on the substrate 2.

After step S4, in the manufacturing method of the display device 1 according to the present embodiment, the inorganic layer 5 is formed by application (step S14). For example, in step S14, the precursor of the second inorganic material may be individually ejected onto each hole transport layer 32 and between the banks 6 in a plan view of the substrate 2 by the inkjet method or the like. In this case, the inorganic layer 5 may be formed by subsequently heating the precursor of the second inorganic material. Accordingly, as illustrated in step S14 of FIG. 15, the inorganic layer 5 may be formed on the hole transport layer 32 and at a position including the side surface of the bank 6.

Here, as described above, the inorganic layer 5 may have the same configuration regardless of the position in a plan view of the substrate 2. Thus, even when the precursor of the second inorganic material ejected in the formation of the inorganic layer 5 by application flows beyond the bank 6, the influence on the post-process and the influence on the performance of the manufactured display device 1 are small.

Thus, in step S14, an ejection amount of the precursor of the second inorganic material to each position corresponding to a respective one of the subpixels may be increased. Alternatively, in step S14, a layer of the precursor of the second inorganic material may be formed in common to the plurality of subpixels. Accordingly, in step S14, the film formability of the inorganic layer 5 at each position can be improved, and thus the yield of the display device 1 can be improved.

Next, the forming process of the quantum dot layer 33 is executed. Also in the present embodiment, in the forming process of the quantum dot layer 33, an example of a method of forming the red quantum dot layer 33R, the green quantum dot layer 33G, and the blue quantum dot layer 33B in this order will be described.

In the forming process of the quantum dot layer 33 according to the present embodiment, first, the quantum dot material containing the precursor 81 of the first inorganic material 4 and the plurality of quantum dots are ejected (step S15). For example, in step S15 in the forming process of the red quantum dot layer 33R, the quantum dot material is ejected by the inkjet method or the like at a position overlapping the anode 31 corresponding to the red subpixel SPR and between the banks 6 in a plan view of the substrate 2. The quantum dot material includes the precursor 81 and the red quantum dot QDR. Accordingly, as illustrated in step S15-1 of FIG. 15, the red quantum dot material layer 8R is formed at the position overlapping the anode 31 corresponding to the red subpixel SPR in a plan view of the substrate 2.

Here, as described above, the luminescent color of the quantum dot contained in the quantum dot layer 33 varies depending on the subpixel. Thus, from the viewpoint of reducing color mixing between light-emitting elements adjacent to each other, in order to reduce the possibility that the ejected quantum dot material flows beyond the bank 6, the amount of the quantum dot material ejected in step S15 may be a minimum amount. In step S15, at least part of the inorganic layer 5 in contact with the ejected quantum dot material may be dissolved in the quantum dot material.

After step S15, the quantum dot material layer is heated (step S16). Step S16 may be executed by the same method as in step S11 described above. For example, in step 33R in the forming process of the red quantum dot layer S16, as illustrated in step S16-1 of FIG. 15, the red quantum dot layer 33R is formed at the position corresponding to the red subpixel SPR on the inorganic layer 5.

The above-described steps S15 and S16 are repeatedly executed until the quantum dot layers of all luminescent colors are formed. For example, in the present embodiment, a forming process of the green quantum dot layer 33G is executed subsequent to the forming process of the red quantum dot layer 33R.

For example, in step S15 of the forming process of the green quantum dot layer 33G, the quantum dot material containing the precursor 81 and the green quantum dots QDG is ejected at a position overlapping the anode 31 corresponding to the green subpixel SPG and between the banks 6 in a plan view of the substrate 2. Accordingly, as illustrated in step S15-2 of FIG. 16, the green quantum dot material layer 8G is formed at the position overlapping the anode 31 corresponding to the green subpixel SPG in a plan view of the substrate 2.

In step S16 of the forming process of the green quantum dot layer 33G, as illustrated in step S16-2 of FIG. 16, by heating the green quantum dot material layer 8G, the green quantum dot layer 33G is formed at the position corresponding to the green subpixel SPG on the inorganic layer 5. Also in step S16 of the forming process of the green quantum dot layer 33G, the red quantum dots QDR in the red quantum dot layer 33R are protected by the first inorganic material 4. Thus, the first inorganic material 4 can reduce deterioration of the red quantum dot QDR caused by heating of the green quantum dot material layer 8G.

Subsequently, in the same manner as described above, as illustrated in step S16-3 of FIG. 16, by executing step S15 and step S16, the blue quantum dot layer 33B is formed at the position corresponding to the blue subpixel SPB on the inorganic layer 5. As a result, the quantum dot layer 33 is formed. Also in the forming process of the blue quantum dot layer 33B, the red quantum dots QDR and the green quantum dots QDG are protected by the first inorganic material 4. Thus, the first inorganic material 4 can reduce the influence of the forming process of the blue quantum dot layer 33B on the red quantum dots QDR and the green quantum dots QDG.

As described above, in the example of the manufacturing method of the display device 1 according to the present embodiment, the quantum dot layer 33 is formed by individually ejecting the material containing the quantum dots to each position corresponding to a respective one of the subpixels. Thus, in the example of the manufacturing method of the display device 1 according to the present embodiment, the process of patterning the quantum dot material layer is not necessary. Thus, the manufacturing method of the display device 1 according to the present embodiment can eliminate the need for a process such as patterning and peeling of the photosensitive resin layer 7 that may deteriorate the quantum dots in the formed quantum dot layer 33 and can improve the luminous efficiency and reliability of the light-emitting element.

In step S15 of the manufacturing method of the display device 1 according to the present embodiment, the process of ejecting the material containing the precursor 81 of the first inorganic material 4 and the quantum dots to each position corresponding to a respective one of the subpixels has been described as an example, but the embodiment is not limited thereto. For example, in the present embodiment, in step S15, the quantum dot layer 33 may be directly formed by ejecting a material containing the first inorganic material 4 and the quantum dots. In this case, execution of step S16 may be omitted.

After the quantum dot layer 33 is formed, by executing the above-described steps S12 and S13, the electron transport layer 34 and the cathode 35 are formed, the formation of the light-emitting element layer 3 illustrated in FIG. 13 is completed, and the manufacturing process of the display device 1 is completed. In step S12, the electron transport layer 34 may be formed by individually ejecting the material of the electron transport layer 34 onto each quantum dot layer 33 and between the banks 6 in a plan view of the substrate 2 by an inkjet method or the like.

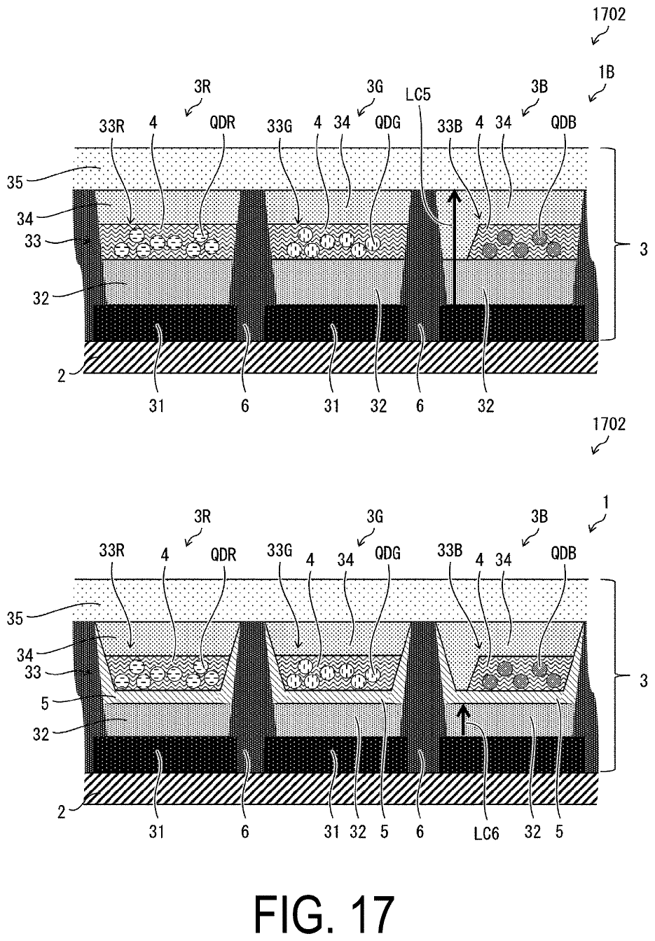

Mechanism for Reducing Leakage Current according to Another Embodiment A mechanism for reducing a leakage current in each light-emitting element of the display device 1 according to the present embodiment will be described in comparison with a display device according to another comparative embodiment. FIG. 17 is a schematic cross-sectional side view 1701 of a display device 1B according to a second comparative embodiment and a schematic cross-sectional side view 1702 of the display device 1 according to the present embodiment.

FIG. 17 illustrates an example of each display device in a case where an offset occurs in a formation position of the blue quantum dot layer 33B in the manufacturing process of each display device. In a case where the quantum dot layer 33 is formed by ejecting the quantum dot material, for example, a positional offset of a nozzle that ejects the quantum dot material may occur. In addition, when the quantum dot material is ejected from the nozzle, an offset of an ejection speed of the quantum dots from the nozzle, an offset of an ejection direction, or the like may occur caused by clogging of the nozzle due to the quantum dots or the precursor 81. Accordingly, when the quantum dot layer 33 is formed by ejecting the quantum dot material, the formation position of the quantum dot layer 33 may be offset. Here, as described above, in the case where the quantum dot layer 33 is formed by ejecting the quantum dot material, the amount of the material to be ejected may be as small as possible in order to reduce color mixing between light-emitting elements adjacent to each other. In this case, the offset of the formation position of the quantum dot layer 33 may be significant.

In a case of forming the light-emitting layer in which the first inorganic material 4 is filled with the quantum dots, as described above, it is necessary to heat a material containing the precursor 81 at a high temperature in order to form the first inorganic material 4 by reacting the precursor 81. In the heating in the present embodiment, heat is easily applied to the substrate 2, and thus for example, a positional offset of the substrate 2 with respect to a nozzle position at which the application material is ejected is likely to occur. In addition, in the present embodiment, when the material of the quantum dot material layer is applied, clogging of the nozzle due to the precursor 8 is likely to occur. Even in such a case, according to the disclosure, the leakage current described below can be effectively reduced and the decrease in the luminous efficiency of each light-emitting element can be suppressed.

FIG. 17 illustrates an example in which a position where the anode 31 of the blue subpixel SPB and the blue quantum dot layer 33B do not overlap each other in a plan view of the substrate 2 is generated in each display device due to the offset of the formation position of the blue quantum dot layer 33B.

The display device 1B according to the second comparative embodiment does not include the inorganic layer 5 as compared with the display device 1 according to the present embodiment. Thus, in the display device 1, when the offset of the formation position of the quantum dot layer 33 occurs, a portion where the hole transport layer 32 and the electron transport layer 34 are in contact with each other may be generated. At this position, as illustrated in the schematic cross-sectional side view 1701 of the display device 1B in FIG. 17, a leakage current LC5 may be generated to flow from the anode 31 to the cathode 35 without passing through the quantum dot layer 33. Thus, when an offset occurs in the formation position of the quantum dot layer 33 in the manufacturing process of the display device 1B, the luminous efficiency of each light-emitting element of the display device 1B may be reduced.

On the other hand, the display device 1 according to the present embodiment includes the inorganic layer 5. Thus, when the offset of the formation position of the quantum dot layer 33 occurs, the portion where the electron transport layer 34 and the inorganic layer 5 are in contact with each other may increase, but the portion where the hole transport layer 32 and the electron transport layer 34 are in contact with each other is not formed. Thus, as illustrated in the schematic cross-sectional side view 1702 of the display device 1 in FIG. 17, the inorganic layer 5 reduces a leakage current LC6 flowing from the anode 31 to the electron transport layer 34 and the cathode 35 via the hole transport layer 32 by bypassing the quantum dot layer 33. Thus, also in the present embodiment, regardless of the offset of the formation position of the quantum dot layer 33, the display device 1 reduces the intensity of the generated leakage current, and suppresses a decrease in the luminous efficiency of each light-emitting element.

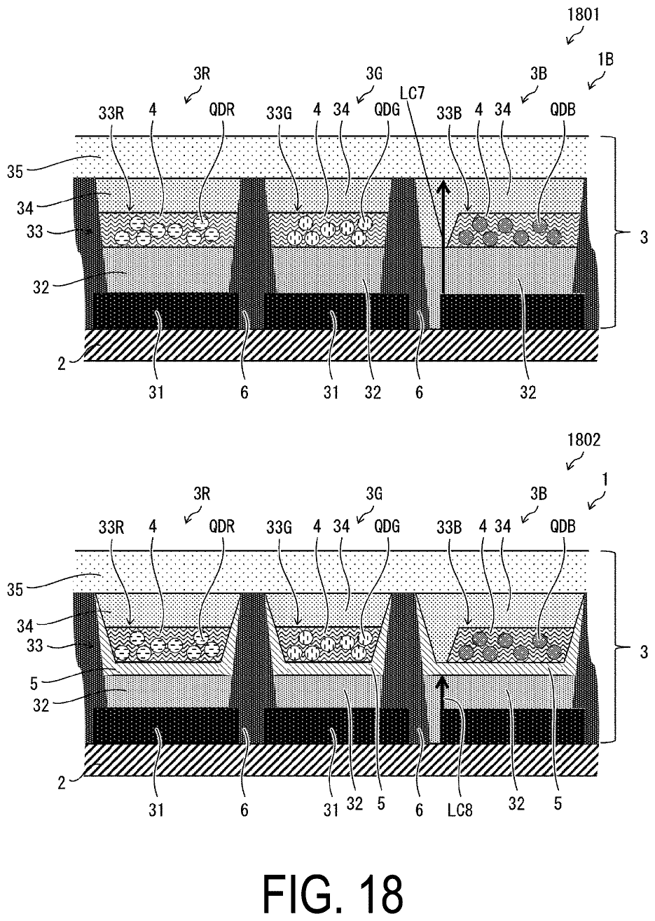

Mechanism for Reducing Leakage Current Caused by Offset of Bank Formation Position Another mechanism for reducing a leakage current in each light-emitting element of the display device 1 according to the present embodiment will be described in comparison with a display device according to a comparative embodiment. FIG. 18 is a schematic cross-sectional side view 1801 of a display device 1B according to a second comparative embodiment and a schematic cross-sectional side view 1802 of the display device 1 according to the present embodiment.

FIG. 18 illustrates an example of each display device in a case where an offset occurs in the formation position of the bank 6 between the green light-emitting element 3G and the blue light-emitting element 3B in the manufacturing process of each display device. In particular, in the present embodiment, the formation position of the bank 6 is offset so as to be closer to the green subpixel SPG. In this case, for example, even when an offset does not occur in an ejection position of the quantum dot material in the forming process of the blue quantum dot layer 33B, wet-spreading of the material may not sufficient between the banks 6.

Thus, in the display device 1i, when the offset occurs in the formation position of the bank 6, a portion where the hole transport layer 32 and the electron transport layer 34 are in contact with each other may be generated. At this position, as illustrated in the schematic cross-sectional side view 1801 of the display device 1B in FIG. 18, a leakage current LC7 may be generated to flow from the anode 31 to the cathode 35 without passing through the quantum dot layer 33. Thus, even when an offset occurs in the formation position of the bank 6 in the manufacturing process of the display device 1B, the luminous efficiency of each light-emitting element of the display device 1B may be reduced.

On the other hand, the display device 1 according to the present embodiment includes the inorganic layer 5. Thus, when the offset of the formation position of the bank 6 occurs, the portion where the electron transport layer 34 and the inorganic layer 5 are in contact with each other may increase, but the portion where the hole transport layer 32 and the electron transport layer 34 are in contact with each other is not formed. Thus, as illustrated in the schematic cross-sectional side view 1802 of the display device 1 in FIG. 18, the inorganic layer 5 reduces a leakage current LC8 flowing from the anode 31 to the electron transport layer 34 and the cathode 35 via the hole transport layer 32 by bypassing the quantum dot layer 33. Thus, also in the present embodiment, regardless of the offset of the formation position of the bank 6, the display device 1 reduces the intensity of the generated leakage current, and suppresses a decrease in the luminous efficiency of each light-emitting element.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A display device comprising:
a substrate;
a plurality of light-emitting elements on the substrate, the plurality of light-emitting elements including a first electrode, a second electrode, and a quantum dot layer located between the first electrode and the second electrode and including a plurality of quantum dots and a first inorganic material with which spaces between the plurality of quantum dots are filled; and
an inorganic layer located between at least two of the light-emitting elements and including a second inorganic material including a semiconductor having a band gap of 2.8 eV or more or an insulator.

2. The display device according to claim 1,
wherein part of the inorganic layer is located between the first electrode and the second electrode of the light-emitting element.

3. The display device according to claim 1,
wherein each of the plurality of light-emitting elements further includes a charge transport layer located at least one of between the first electrode and the quantum dot layer or between the second electrode and the quantum dot layer,
the inorganic layer is in contact with at least one of the charge transport layers, and
a band gap of the second inorganic material is equal to or more than a band gap of the charge transport layer with which the inorganic layer is in contact.

4. The display device according to claim 3,
wherein the band gap of the second inorganic material has a difference of 0.2 eV or more from the band gap of the charge transport layer with which the inorganic layer is in contact.

5. The display device according to claim 3,
wherein the charge transport layer includes a first charge transport layer located between the first electrode and the quantum dot layer, and a second charge transport layer located between the second electrode and the quantum dot layer, and
at least part of the inorganic layer is located between the first charge transport layer and the second charge transport layer.

6. The display device according to claim 5, further comprising:
banks partitioning the plurality of light-emitting elements,
wherein at least part of the inorganic layer is located between one of the charge transport layers and the bank.

7. The display device according to claim 1,
wherein at least part of the inorganic layer overlaps a periphery of the quantum dot layer in a plan view of the substrate.

8. The display device according to claim 1,
wherein at least part of the inorganic layer overlaps the first electrode in a plan view of the substrate.

9. The display device according to claim 1,
wherein part of the inorganic layer overlaps the quantum dot layer in a plan view of the substrate.

10. The display device according to claim 9,
wherein a thickness of the inorganic layer in contact with the quantum dot layer is smaller than a thickness of the inorganic layer overlapping a periphery of the quantum dot layer in a plan view of the substrate.

11. The display device according to claim 1,
wherein the inorganic layer is formed only at a position overlapping a periphery of the quantum dot layer in a plan view of the substrate.

12. The display device according to claim 1,
wherein the first inorganic material and the second inorganic material include the same inorganic material.

13. The display device according to claim 1,
wherein the first inorganic material and the second inorganic material include zinc sulfide or zinc magnesium sulfide.

14. The display device according to claim 1,
wherein the inorganic layer includes aluminum oxide.

15. The display device according to claim 1,
wherein a film thickness of the inorganic layer is 1 nm or more and 30 nm or less.

16. The display device according to claim 15,
wherein the film thickness of the inorganic layer is 1 nm or more and 2 nm or less.

17. A manufacturing method of a display device comprising:
providing a substrate;
forming a plurality of light-emitting elements including forming a plurality of first electrodes on the substrate, forming a plurality of quantum dot layers each including a plurality of quantum dots and a first inorganic material with which spaces between the plurality of quantum dots are filled at a position overlapping a respective one of the first electrodes in a plan view of the substrate, and forming at least one second electrode at a position overlapping a respective one of the first electrodes in a plan view of the substrate; and
forming an inorganic layer located between at least two of the light-emitting elements and including a second inorganic material including a semiconductor having a band gap of 2.8 eV or more or an insulator.

18. The manufacturing method of a display device according to claim 17,
wherein the forming the inorganic layer includes a film formation of the inorganic layer including the second inorganic material at a position overlapping at least one of the plurality of first electrodes in a plan view of the substrate, and
the forming the quantum dot layer includes a film formation of a quantum dot material layer including the first inorganic material and the plurality of quantum dots on the inorganic layer.

19. The manufacturing method of a display device according to claim 18,
wherein the forming the plurality of light-emitting elements further includes forming a charge transport layer on at least each of the plurality of first electrodes, and
the forming the inorganic layer includes a film formation of the inorganic layer on the charge transport layer.

20-22. (canceled)

23. A display device comprising:
a substrate;
a plurality of light-emitting elements on the substrate, the plurality of light-emitting elements including a first electrode, a second electrode, and a quantum dot layer located between the first electrode and the second electrode and including a plurality of quantum dots and a first inorganic material; and
an inorganic layer located between at least two of the light-emitting elements and including a second inorganic material including a semiconductor having a band gap of 2.8 eV or more or an insulator.
